(19) United States
(12) Patent Application Publication
(10) Pub. No.: US 2007/0049778 A1
(43) Pub. Date: Mar. 1, 2007

(54) Anthracene derivative and hole transporting material, light emitting element, and electronic appliance using the same

(75) Inventors: Ryoji Nomura, Yamato (JP); Sachiko Kawakami, Isehara (JP)

Correspondence Address: ERIC ROBINSON, PMB 955, 21010 SOUTHBANK ST., POTOMAC FALLS, VA, 20165, US

(73) Assignee: Semiconductor Energy laboratory Co., Ltd., Atsugi-shi (JP)

(21) Appl. No.: 11/509,733

(22) Filed: Aug. 25, 2006

(30) Foreign Application Priority Data
Aug. 29, 2005 (JP) 2005-247021
Aug. 30, 2005 (JP) 2005-249899

(51) Int. Cl. H01L 51/54; C09K 11/06

(52) U.S. Cl. 585/26; 428/690; 428/917; 313/504; 313/506; 257/E51.049

(57) ABSTRACT

It is an object of the present invention to provide a substance capable of contributing to obtaining a light emitting element with a low driving voltage and long lifetime. An anthracene derivative represented by a general formula (1) is provided. In the general formula (1), each of R¹ to R⁸ represents hydrogen or an alkyl group having 1 to 4 carbon atoms. Further, each of R⁹ to R¹⁷ represents hydrogen, an alkyl group having 1 to 4 carbon atoms, or a substituted or unsubstituted aryl group. Such an anthracene derivative can be hardly crystallized, and can be superior in a carrier transporting property. Therefore, by using the anthracene derivative, a light emitting element with a low driving voltage and long lifetime can be manufactured.

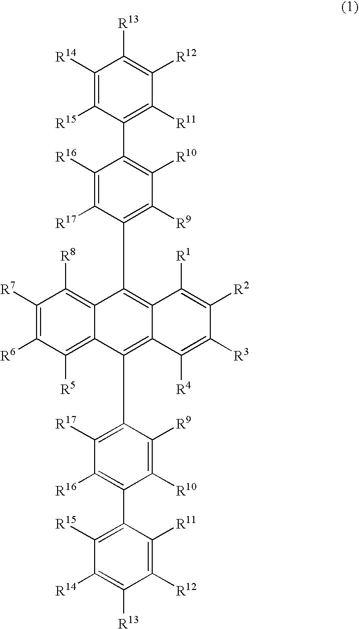

### TECHNICAL FIELD

The present invention relates to a substance that can be used as a material for manufacturing a light emitting element.

### BACKGROUND ART

In recent years, many light emitting elements utilized for a display and the like have a structure in which a layer including a light-emitting substance is sandwiched between a pair of electrodes. In such a light emitting element, electrons injected from one of the electrodes and holes injected from the other electrode are recombined to form excitons. Then, when the excitons return to a ground state, the light emitting element emits light.

In a field of a light emitting element, in order to obtain light emitting element having high luminous efficiency and a long lifetime with little deterioration, a substance to be a material for manufacturing an element has been researched in various ways.

Incidentally, as one of causes for deterioration of a light emitting element, crystallization of a substance forming a light emitting element can be cited. In Patent Document 1 (Patent Document 1: Japanese Patent Application Laid-Open No. 2004-210786), a diphenylanthracene derivative is disclosed, which easily keeps an amorphous state. Further, improvement of luminance and a driving voltage in a light emitting element that is formed using the diphenylanthracene derivative is described therein.

### DISCLOSURE OF INVENTION

However, a light emitting element that is formed using a conventional diphenylanthracene derivative has a high driving voltage. Therefore, the light emitting element can not be fulfilled a requirement of being driven with a low voltage in order to realize low power consumption and downsizing of power supply.

Thus, it is an object of the present invention to provide a substance capable of contributing to obtaining a long lifetime light emitting element with a lower driving voltage.

One feature of the present invention is an anthracene derivative represented by a general formula (1).

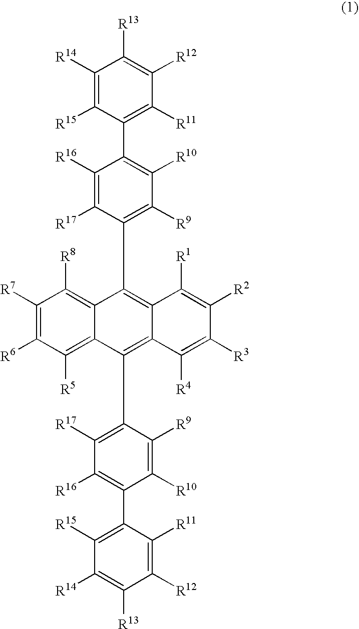

In the general formula (1), each of R¹ to R⁸ represents hydrogen or an alkyl group having 1 to 4 carbon atoms. Further, each of R⁹ to R¹⁷ represents hydrogen, an alkyl group having 1 to 4 carbon atoms, or a substituted or unsubstituted aryl group.

Another feature of the present invention is an anthracene derivative represented by a general formula (2).

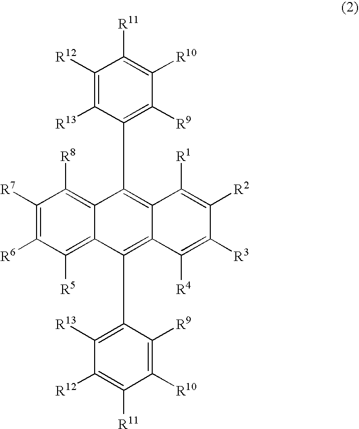

In the general formula (2), each of R¹ to R⁸ represents hydrogen or an alkyl group having 1 to 4 carbon atoms. Further, each of R⁹ to R¹³ represents hydrogen, an alkyl group having 1 to 4 carbon atoms, or a substituted or unsubstituted aryl group.

Another feature of the present invention is an anthracene derivative represented by a general formula (3).

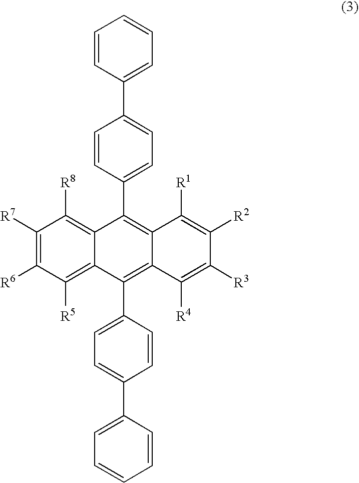

In the general formula (3), each of R¹ to R⁸ represents hydrogen or an alkyl group having 1 to 4 carbon atoms.

Another feature of the present invention is an anthracene derivative in which any one of the R¹ to R⁸ is an alkyl group having 3 carbon atoms in any one of the general formulas (1) to (3).

Another feature of the present invention is an anthtracene derivative represented by a structural formula (4).

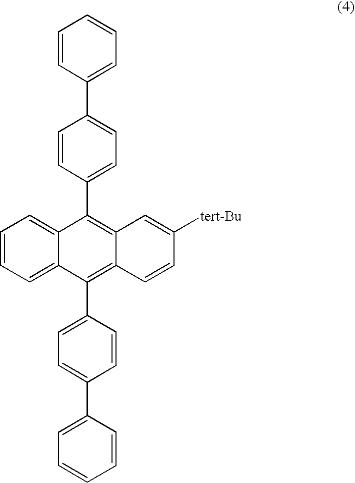

Another feature of the present invention is a hole transporting material represented by any one of the general formulas (1) to (3).

Another feature of the present invention is a light emitting element having an anthracene derivative represented by any one of the general formulas (1) to (3), between a pair of electrodes.

Another feature of the present invention is a light emitting element having a hole transporting material represented by any one of the general formulas (1) to (3), between a pair of electrodes.

Another feature of the present invention is a light emitting device using a light emitting element having an antrancene derivative represented by any one of the general formulas (1) to (3) in a pixel portion.

Another feature of the present invention is an electronic appliance in which a light emitting element having an anthracene derivative represented by any one of the general formulas (1) to (3) is included at least in a display portion or a light source portion, and a control part for driving the light emitting element is included.

In accordance with the present invention, an anthracene derivative that can be hardly crystallized, and can be superior in a carrier transporting property can be obtained. In addition, a light emitting element of the present invention having such a substance can achieve reduction of a driving voltage and a long lifetime. Further, by manufacturing a light emitting device with the use of the light emitting element, a highly reliable light emitting device with low power consumption and a long lifetime, and an electronic appliance incorporating the light emitting device can be provided.

### BRIEF DESCRIPTION OF DRAWINGS

FIG. 1 shows a view for explaining an element structure of a light emitting element of the present invention;

FIGS. 2A and 2B show views of a light emitting device using a light emitting element of the present invention;

FIGS. 3A and 3B show views of a light emitting device using a light emitting element of the present invention;

FIGS. 4A to 4D show views of electronic appliances using a light emitting element of the present invention;

FIG. 5 shows an ¹H-NMR chart of t-BuDBA obtained by Embodiment 1 (Synthesis Example 1);

FIG. 6 shows a view for explaining an element structure of a light emitting element manufactured in Embodiment 2;

FIGS. 7A to 7C show graphs for showing operating characteristics of a light emitting element manufactured in Embodiment 2;

FIG. 8 shows a view for explaining an element structure of a light emitting element manufactured in Embodiment 3;

FIGS. 9A to 9C show graphs for showing operating characteristics of a light emitting element manufactured in Embodiment 3;

FIGS. 10A and 10B show graphs for showing results of reliability tests of a light emitting element manufactured in Embodiment 3;

FIG. 11 shows a view for explaining an element structure of a light emitting element manufactured in Embodiment 4;

FIGS. 12A to 12C show graphs for showing operating characteristics of a light emitting element manufactured in Embodiment 4;

FIGS. 13A and 13B show graphs for showing results of reliability tests of a light emitting element manufactured in Embodiment 4;

FIG. 14 shows a view of a cellular phone using a light emitting element of the present invention;

FIG. 15 shows a view for explaining an element structure of a light emitting element manufactured in Embodiment 5; and

FIGS. 16A to 16C show graphs for showing operating characteristics of a light emitting element manufactured in Embodiment 5.

### BEST MODE FOR CARRYING OUT THE INVENTION

Hereinafter, one mode of the present invention will be explained. However, the present invention is easily understood by those skilled in the art that various changes and modifications are possible, unless such changes and modifications depart from the content and the scope of the present invention. Therefore, the present invention is not construed as being limited to the description of the following Embodiments.

### Embodiment Mode 1

One mode of the present invention is an anthracene derivative represented by structural formulas (4) to (24).

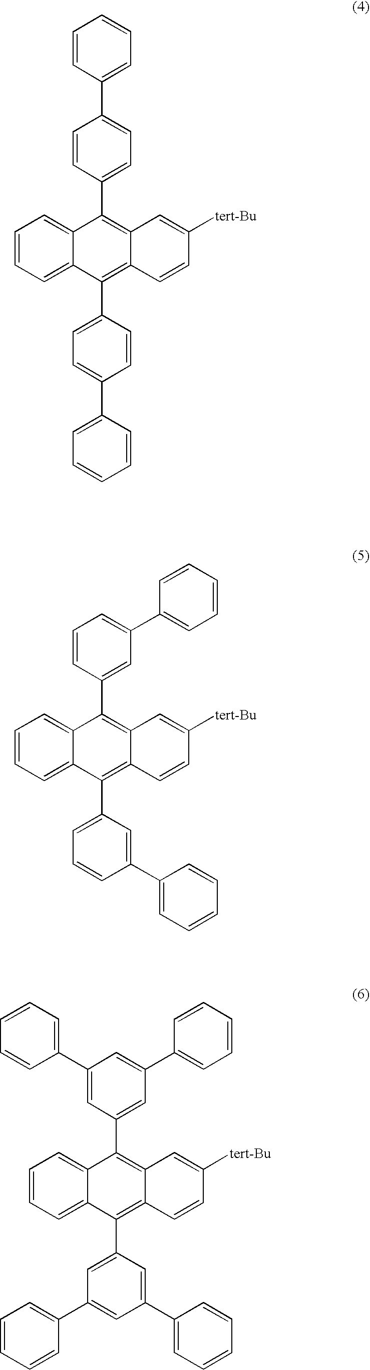

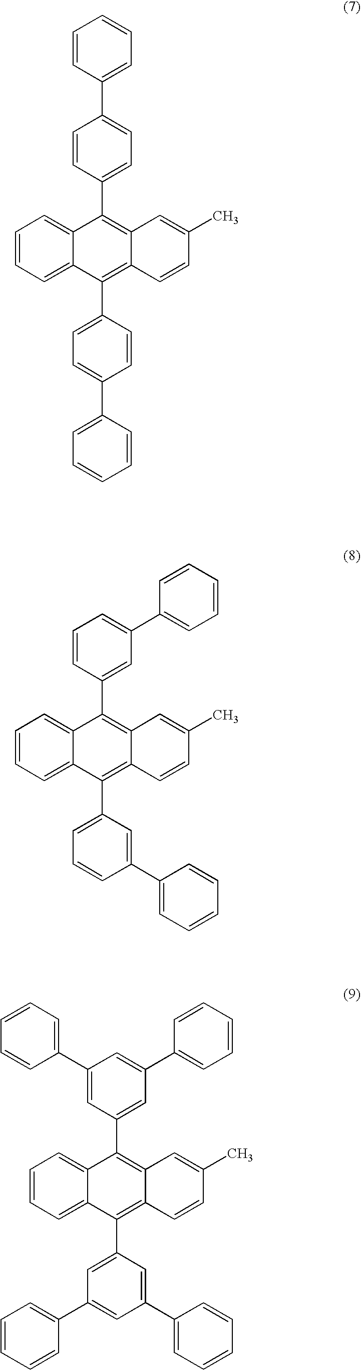

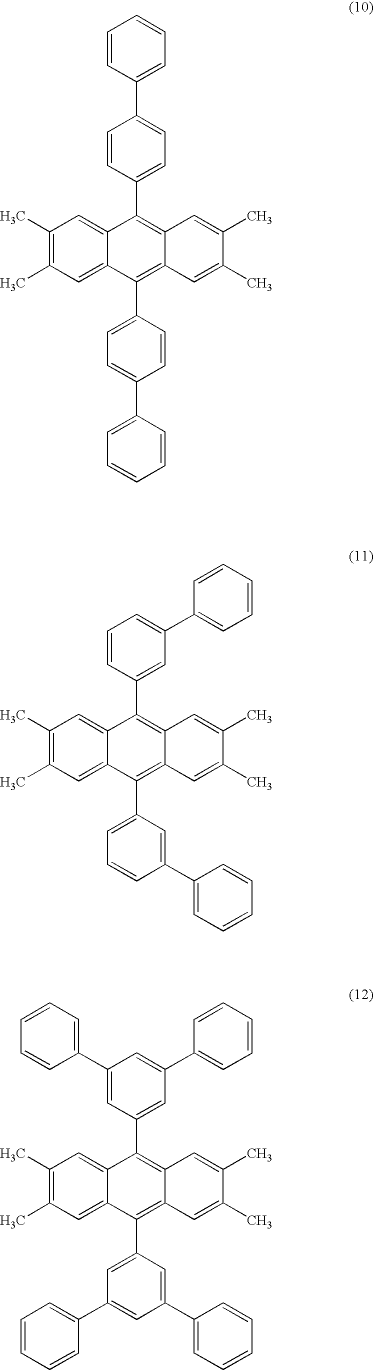

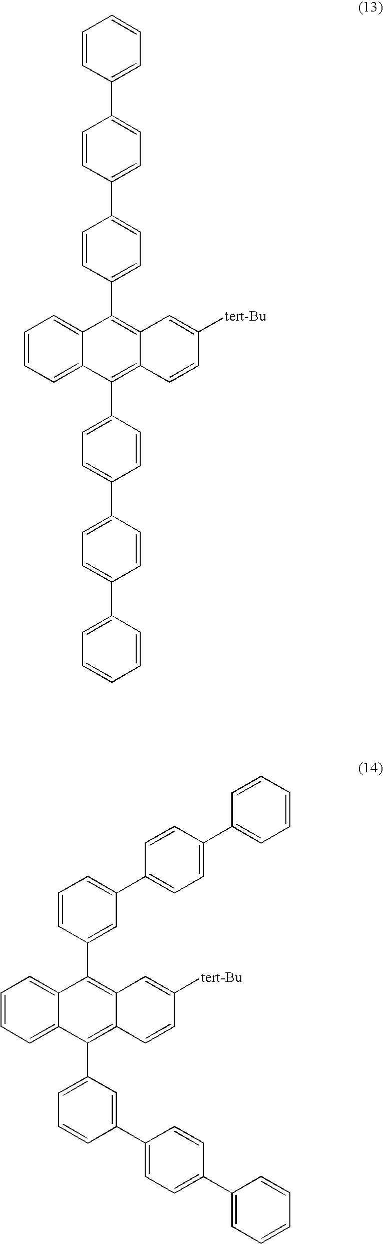

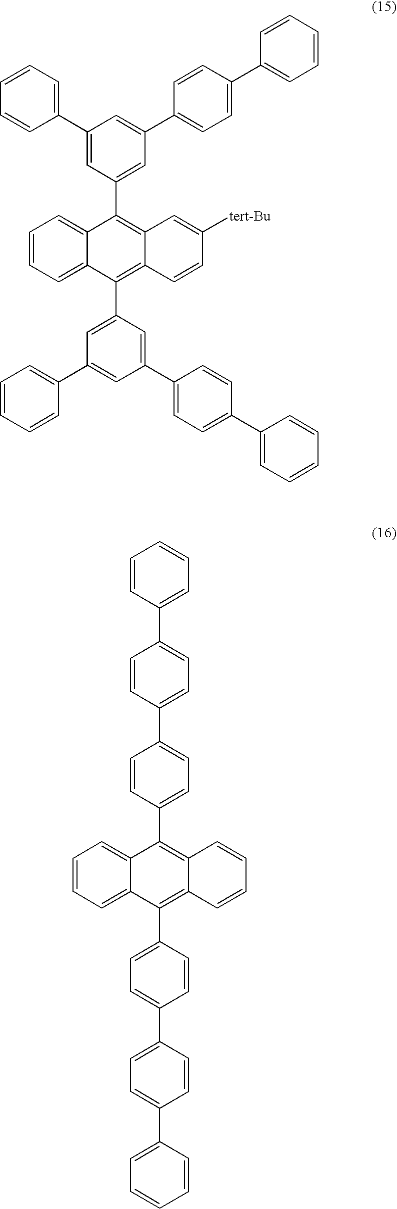

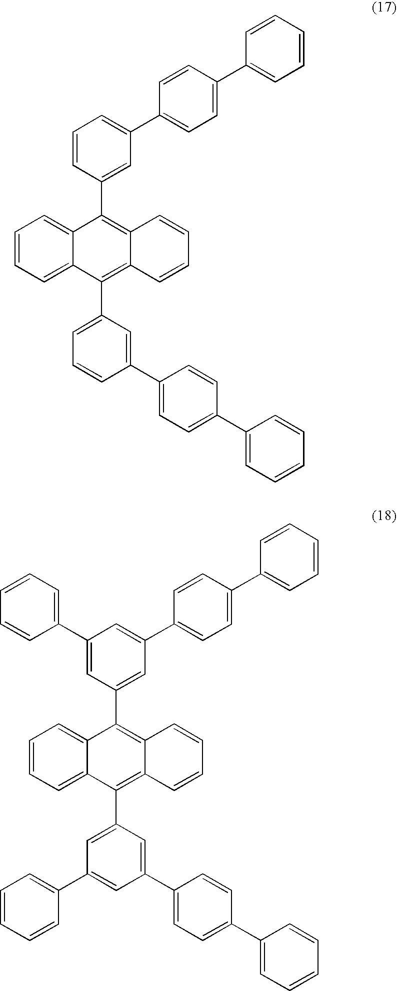

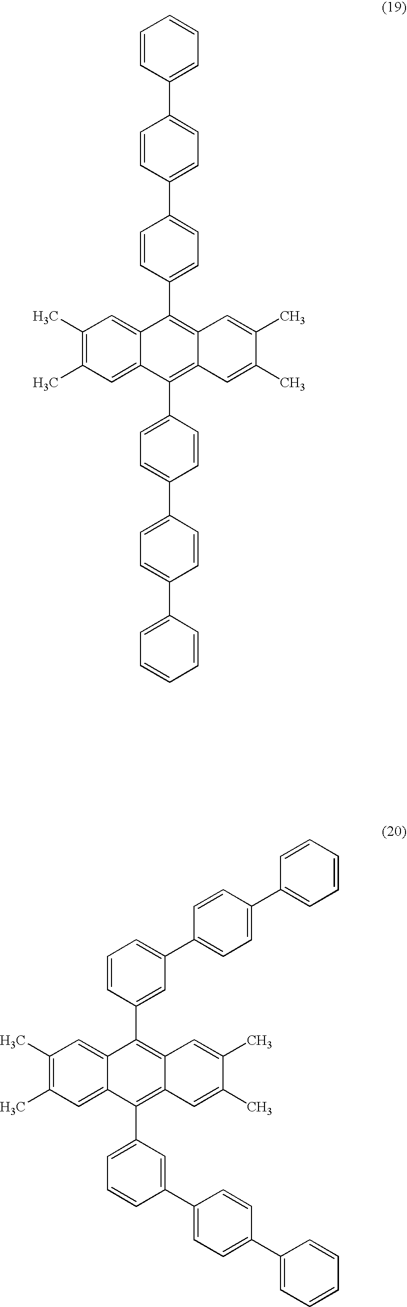

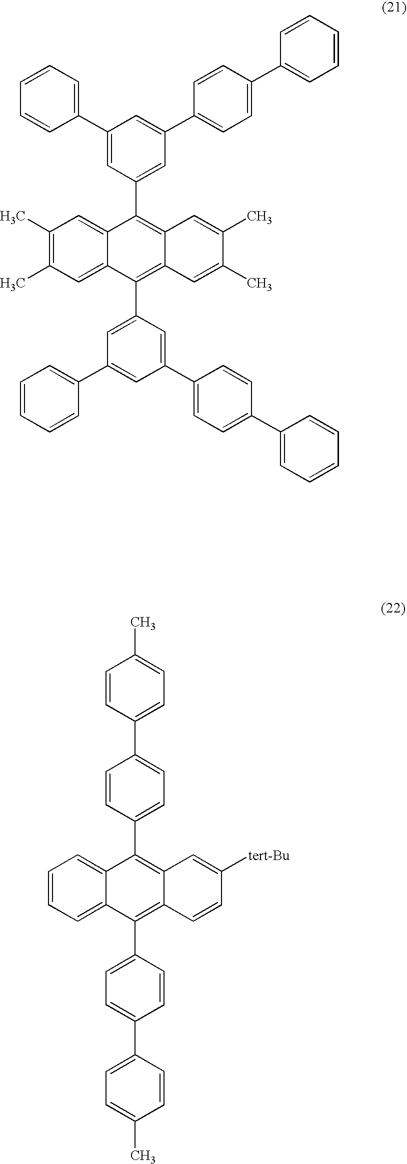

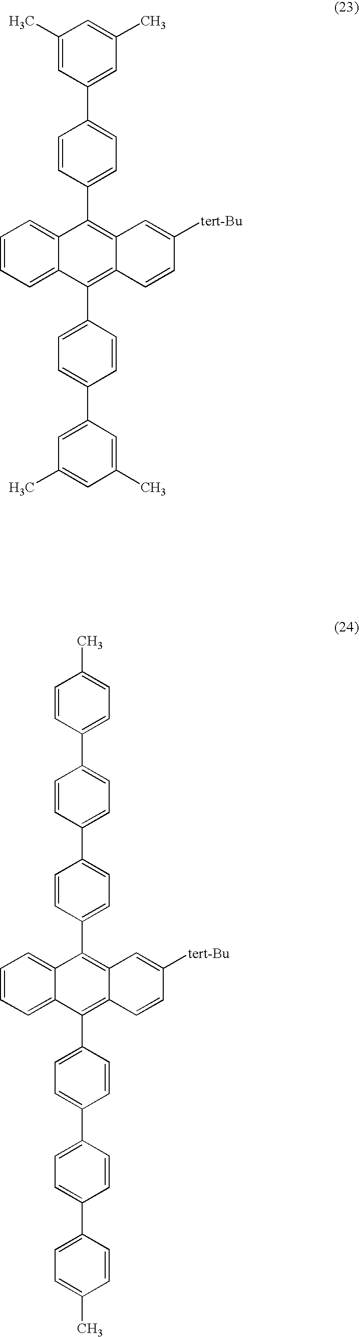

Since the anthracene derivatives of the present invention described above have a high volume structure, crystallization and dimerization of an anthracene skeleton can be suppressed. Further, the anthracene derivative of the present invention has a superior carrier transporting property.

### Embodiment Mode 2

A synthesis method of an anthracene derivative represented by a general formula (25) of the present invention will be explained below. It is to be noted that an anthracene derivative of the present invention is not limited to a synthesis method described in this embodiment mode, and the anthracene derivative may be synthesized by another synthesis method.

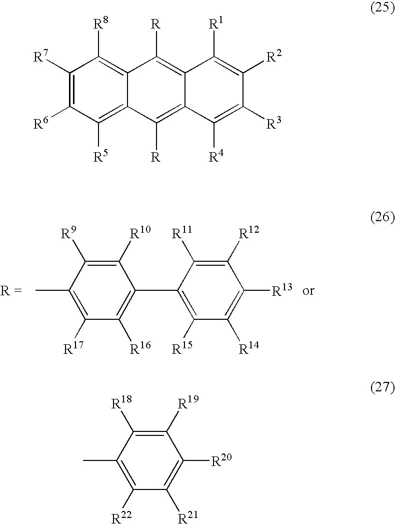

In the general formula (25), each of R¹ to R⁸ represents hydrogen or an alkyl group having 1 to 4 carbon atoms. Further, R represents the above general formula (26) or (27). Each of R⁹ to R²² represents hydrogen, an alkyl group having 1 to 4 carbon atoms, or a substituted or unsubstituted aryl group.

As shown in a synthesis scheme (a-1), a halogen compound such as bromide or iodide having the general formula (26) or (27) and alkyllithium are reacted with each other. Then, an obtained compound and a compound having an anthraquinone skeleton are reacted with each other, and water is added thereto, whereby a diol body (a compound A) corresponding to a starting substance can be prepared.

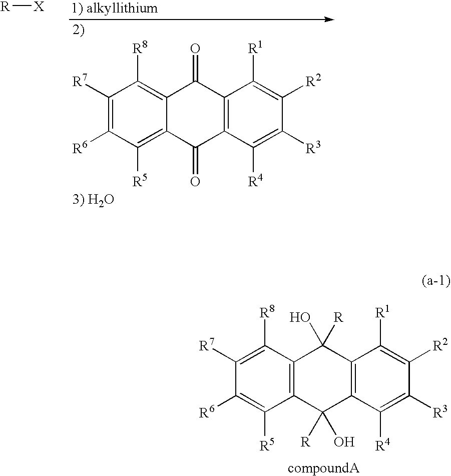

By elimination reaction of a hydroxyl group of the obtained compound A in such a manner, an anthracene derivative of the present invention can be obtained. A synthesis scheme (a-2) is shown below.

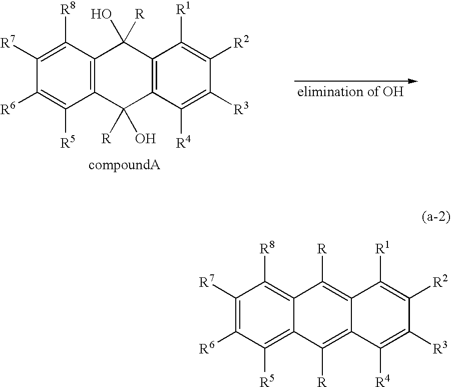

Since the anthracene derivative, which is obtained as described above, has a high volume structure, crystallization and dimerization of an anthracene skeleton can be suppressed. Further, the anthracene derivative has a superior transporting property.

### Embodiment Mode 3

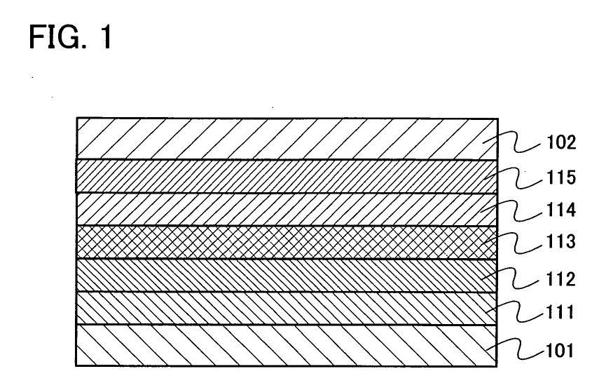

A mode of a light emitting element using an anthracene derivative of the present invention as a hole transporting material will be explained with reference to FIG. 1.

In FIG. 1, in addition to a light emitting layer 113, a hole injecting layer 111, a hole transporting layer 112, an electron transporting layer 114, an electron injecting layer 115, and the like are provided between a first electrode 101 and a second electrode 102. These layers are stacked so that holes are injected from a first electrode 101 side and electrons are injected form a second electrode 102 side, when a voltage is applied so that potential of the first electrode 101 is higher than that of the second electrode 102.

In such a light emitting element, holes injected from the first electrode 101 side and electrons injected form the second electrode 102 side are recombined in the light emitting element 113 to make a light emitting substance be an excited state. Then, when the light emitting substance in the excited state returns to a ground state, light is emitted. As the light emitting substance, any substance is acceptable as long as luminescence (electroluminescence) is obtained.

A substance for forming the light emitting layer 113 is not particularly limited. The light emitting layer 113 may be a layer formed only of a light emitting substance; however, it is preferably a layer in which a light emitting substance is mixed to be dispersed in a layer made of a substance (a host) having a larger energy gap than the light emitting substance in a case where concentration quenching is caused. Thus, concentration quenching of a light emitting substance can be prevented. It is to be noted that an energy gap indicates an energy difference between a lowest unoccupied molecular orbital (LUMO) level and a highest occupied molecular orbital (HOMO) level.

Further, a light emitting substance is not particularly limited. A substance capable of emitting light of a desired emission wavelength may be used. For example, when reddish emission is desired to be obtained, a substance that exhibits emission with a peak from 600 to 680 nm in an emission spectrum such as 4-dicyanomethylene-2-isopropyl-6-[2-(1,1,7,7-tetramethyljulolidine-9-yl)ethenyl]-4H-pyran (abbreviation: DCJTI), 4-dicyanomethylene-2-methyl-6-[2-(1,1,7,7-tetramethyljulolidine-9-yl)ethenyl]-4H-pyran (abbreviation: DCJT), 4-dicyanomethylene-2-tert-butyl-6-[2-(1,1,7,7-tetramethyljulolidine-9-yl)ethenyl]-4H-pyran (abbreviation: DCJTB), periflanthene, or 2,5-dicyano-1,4-bis[2-(10-methoxy-1,1,7,7-tetramethyljulolidine-9-yl)ethenyl]benzene can be used. When greenish emission is desired to be obtained, a substance that exhibits emission with a peak from 500 to 550 nm in an emission spectrum such as N,N′-dimethylquinacridone (abbreviation: DMQd), coumarin 6, coumarin 545T, tris(8-quinolinolato)aluminum (abbreviation: Alq), or N,N′-diphenylquinacridone (abbreviation: DPQd) can be used. In addition, when bluish emission is desired to be obtained, a substance that exhibits emission with a peak from 420 to 500 nm in an emission spectrum such as 9,10-bis(2-naphthyl)-tert-butylanthracene (abbreviation: t-BuDNA), 9,9′-bianthryl, 9,10-diphenylanthracene (abbreviation: DPA), 9,10-bis(2-naphthyl)anthracene (abbreviation: DNA), bis(2-methyl-8-quinolinolato)-4-phenylphenolato-gallium (abbreviation: BGaq), bis(2-methyl-8-quinolinolato)-4-phenylphenolato-aluminum (abbreviation: BAlq), or 9-(4-{N-[4-(9-carbarizolyl)phenyl]-N-phenylamino}phenyl)-10-phenylanthracene (abbreviation: YGAPA) can be used.

A substance for putting a light emitting substance into a dispersion state is not particularly limited. For example, a metal complex such as bis[2-(2-hydroxyphenyl)pyridinato]zinc (abbreviation: Znpp₂) or bis[2-(2-hydroxyphenyl)benzoxazolato]zinc (abbreviation: ZnBOX), or the like can be used as well as an anthracene derivative such as 9,10-di(2-naphthyl)-2-tert-butylanthracene (abbreviation: t-BuDNA) or a carbazole derivative such as 4,4′-bis(N-carbazolyl)biphenyl (abbreviation: CBP). Further, an anthracene derivative of the present invention can be used as a substance for putting a light emitting substance into a dispersion state.

An anode material for forming the first electrode 101 is not particularly limited, and a metal, an alloy, an electric conductive compound, and a mixture thereof, each of which has a high work function (work function of 4.0 eV or higher) can be preferably used. As a specific example of such an anode material, indium tin oxide (abbreviation: ITO), ITO containing silicon oxide, indium zinc oxide (abbreviation: IZO) formed by mixing 2 to 20 [wt %] of zinc oxide (ZnO) into indium oxide, gold (Au), platinum (Pt), nickel (Ni), tungsten (W), chromium (Cr), molybdenum (Mo), iron (Fe), cobalt (Co), copper (Cu), palladium (Pd), nitride of a metal material (for example, TiN), or the like can be used.

On the other hand, as a substance for forming the second electrode 102, a metal, an alloy, an electric conductive compound, and a compound thereof, each of which has a low work function (work function of 3.8 eV or less) can be used. As a specific example of such a cathode material, an element belonging to group 1 or group 2 of the periodic table, that is an alkali metal such as lithium (Li) and cesium (Cs), an alkaline earth metal such as magnesium (Mg), calcium (Ca) and strontium (Sr), or an alloy (Mg:Ag, Al:Li) containing them can be used. Further, a layer superior in an electron injecting property is provided between the second electrode 102 and the light emitting element 113 so as to be stacked with the second electrode. Therefore, various conductive materials, which include a material such as Al, Ag, ITO, or ITO containing silicon oxide for a material of the first electrode 101, can be used as the second electrode 102 regardless of high or low of work function. Furthermore, a material particularly superior in an electron injecting function is used for the electron injecting layer 115, which will be described below, whereby a similar effect can be obtained.

It is to be noted that, in order to extract emitted light to outside, one or both the first electrode 101 and the second electrode 102 are preferably a transparent electrode or an electrode such as ITO with a thickness of several nm to several tens nm so that visible light can be transmitted.

As shown in FIG. 1, the hole transporting layer 112 is provided between the first electrode 101 and the light emitting layer 113. A hole transporting layer has a function of transporting holes injected from the first electrode 101 side to the light emitting layer 113. In such a manner, the hole transporting layer 112 is provided to separate the first electrode 101 from the light emitting layer 113, whereby quenching light emission due to a metal can be prevented.

In the hole transporting layer 112, a layer formed of an anthracene derivative of the present invention represented by any one of the general formulas (1) to (3) is used. Since an anthracene derivative of the present invention has a high volume structure, crystallization and dimerization of an anthracene skeleton can be suppressed. Further, the anthracene derivative has a superior carrier transporting property. Therefore, by using an anthracene derivative of the present invention, the hole transporting layer 112 superior in a hole transporting property, which can be hardly crystallized, can be formed.

The hole transporting layer 112 may have a multi-layer structure in which two or more layers that are formed of anthracene derivatives of the present invention, each of which represented by any one of the general formulas (1) to (3).

As shown in FIG. 1, the electron transporting layer 114 may be provided between the second electrode 102 and the light emitting layer 113. Here, an electron transporting layer has a function of transporting electrons injected from the second electrode 102 to the light emitting layer 113. In such a manner, the electron transporting layer 114 is provided to separate the second electrode 102 from the light emitting layer 113, whereby quenching light emission due to a metal can be prevented.

A substance of the electron transporting layer 114 is not particularly limited. A substance formed of a metal complex having a quinoline skeleton or a benzoquinoline skeleton such as tris(8-quinolinolato)aluminum (abbreviation: Alq), tris(5-methyl-8-quinolinolato)aluminum (abbreviation: Almq₃), bis(10-hydroxybenzo[h]-quinolinato)beryllium (abbreviation: BeBq₂), or bis(2-methyl-8-quinolinolato)-4-phenylphenolato-aluminum (abbreviation: BAlq), or the like can be used. In addition, a substance formed of a metal complex having an oxazole-based ligand or thiazole-based ligand such as bis[2-(2-hydroxyphenyl)-benzoxazolato]zinc (abbreviation: Zn(BOX)₂) or bis[2-(2-hydroxyphenyl)-benzothiazolato]zinc (abbreviation: Zn(BTZ)₂), or the like may be used. A substance formed using 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproin (abbreviation: BCP), or the like may be used. The electron transporting layer 114 is preferably formed using a substance having higher electron mobility than hole mobility as described above. Much preferably, the electron transporting layer 114 is formed using a substance having electron mobility of 10⁻⁶ cm²/Vs or more. It is to be noted that the electron transporting layer 114 may have a multi-layer structure in which two or more layers formed of the above substances are combined.

As shown in FIG. 1, the hole injecting layer 111 may be provided between the first electrode 101 and the hole transporting layer 112. Here, a hole injecting layer has a function of promoting injection of holes from an electrode serving as an anode to the hole transporting layer 112.

A substance of the hole injecting layer 111 is not particularly limited. A substance formed of metal oxide such as molybdenum oxide (MoOx), vanadium oxide (VOx), ruthenium oxide (RuOx), tungsten oxide (WOx), or manganese oxide (MnOx) can be used. In addition, the hole injecting layer 111 can be formed by using a phtalocyanine-based compound such as phthalocyanine (abbreviation: H₂Pc) or copper phthalocyanine (CuPc); an aromatic amine-based compound such as 4,4-bis(N-(4-(N,N-di-m-tolylamino)phenyl-N-phenylamino)biphenyl (abbreviation: DNTPD); a high molecule such as poly(ethylenedioxythiophene)/poly(styrene sulfonate) water solution (PEDOT/PSS), or the like.

Further, a mixture of the metal oxide and a substance having a high hole transporting property may be provided between the first electrode 101 and the hole transporting layer 112. In such a layer, a driving voltage is not increased even in increasing a thickness. Therefore, an optical design utilizing a microcavity effect or an interference effect of light can be performed by adjusting a thickness of the layer. Thus, a high quality light emitting element that has superior color purity and small color change depending on a view angle can be manufactured. A thickness for preventing short-circuit of the first electrode 101 and the second electrode 102 can be selected by effect of concavity and convexity generated on a surface of the first electrode 101 in film formation and a fine residue remaining on the surface of the electrode. It is to be noted that, as a substance having the hole transporting property, an anthracene derivative of the present invention or 9,10-bis(2-naphthyl)-tert-butylanthracene (abbreviation: t-BuDNA) may be used.

As shown in FIG. 1, the electron injecting layer 115 may be provided between the second electrode 102 and the electron transporting layer 114. Here, an electron injecting layer has a function of promoting injection of electrons from an electrode serving as a cathode to the electron transporting layer 114. When the electron transporting layer is not particularly provided, an electron injecting layer may be provided between an electrode serving as a cathode and a light emitting layer to support injections of electrons to the light emitting layer.

A substance of the electron injecting layer 115 is not particularly limited. A substance formed using an alkali metal compound or an alkali earth metal compound such as lithium fluoride (LiF), cesium fluoride (CsF), and calcium fluoride (CaF₂) can be used. In addition, a mixture of a substance having a high electron transporting property such as Alq or 4,4-bis(S-methylbenzoxazol-2-yl)stilbene (BzOs) and an alkali metal or an alkali earth metal such as magnesium or lithium can be used as the electron injection layer 115.

In the light emitting element relating to this embodiment mode described above, each of the hole injecting layer 111, the hole transporting layer 112, the light emitting layer 113, the electron transporting layer 114, and the electron injecting layer 115 may be formed by any of an evaporation method, an ink-jet method, a coating method, and the like. Further, the first electrode 101 and the second electrode 102 may be also formed by any of a sputtering method, an evaporation method, and the like.

Further, in the light emitting element relating to this embodiment mode, when an anthracene derivative of the present invention is used for the hole injecting layer 111, an anthracene derivative of the present invention may not be used for the hole transporting layer 112. In such a case, the hole transporting layer 112 is preferably formed using a substance having a high hole transporting property, and much preferably, formed using a substance having hole mobility of 1×10⁻⁶ cm²/Vs or more. It is to be noted that a substance having a hole transporting property indicates a substance having higher hole mobility than electron mobility. As a specific example of a substance that can be used for forming the hole transporting layer 112, 4,4′-bis[N-(1-naphthyl)-N-phenylamino]biphenyl (abbreviation: NPB), 4,4′-bis[N-(3-methylphenyl)-N-phenylamino]biphenyl (abbreviation: TPD), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis{N-[4-(N,N-di-m-tolylamino)phenyl]-N-phenylamino}biphenyl (abbreviation: DNTPD), 1,3,5-tris[N,N-di(m-tolyl)amino]benzene (abbreviation: m-MTDAB), or 4,4′,4″-tris(N-carbazolyl)triphenylamine (abbreviation: TCTA), phthalocyanine (abbreviation: H₂Pc), copper phthalocyanine (CuPc), vanadyl phthalocyanine (abbreviation: VOPc), or the like can be given.

By using an anthracene derivative of the present invention for a hole transporting material as described above, a light emitting element with a low driving voltage and long lifetime can be obtained. It is to be noted that an anthracene derivative of the present invention may be included at least in one layer as a hole transporting material in a light emitting element of the present invention.

Further, an anthracene derivative of the present invention can be also used as a bluish light emitting substance. By using an anthracene derivative of the present invention in a light emitting substance, a light emitting element having high quantum efficiency can be obtained.

### Embodiment Mode 4

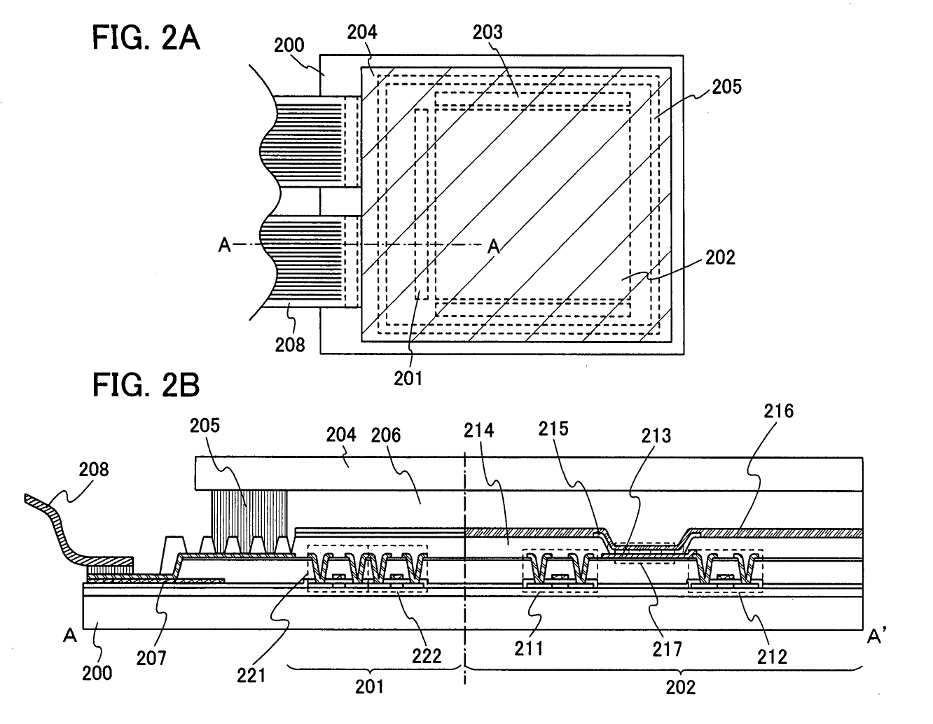

In this embodiment mode, one mode of a light emitting device to which the present invention is applied will be explained with reference to FIGS. 2A and 2B. FIG. 2A is a top view showing a light emitting device, and FIG. 2B is a cross-sectional view taken along a line A-A′ of FIG. 2A. In FIGS. 2A and 2B, corresponding portions to each other are denoted by the same references. Reference numeral 200 denotes a substrate; 201 shown by a dot line, a driver circuit portion (a source driver circuit); 202, a pixel portion; 203, a driver circuit portion (a gate driver circuit); 204, a sealing substrate; and 205, a sealing material. An inside surrounded by the sealing material 205 is a space 206.

Reference numeral 207 denotes a wiring for transmitting a signal inputted to the source driver circuit 201 or the gate driver circuit 203, and receives signals such as a video signal, a clock signal, a start signal, a reset signal, or the like from an FPC (flexible printed circuit) 208 that is to be an external input terminal. Although only the FPC 208 is shown here, a printed wiring board (PWB) may be attached to this FPC. A light emitting device of the present invention includes not only a light emitting device itself but also a light emitting device where an FPC or a PWB is attached thereto.

Next, a cross-sectional structure will be explained with reference to FIG. 2B. The driver circuit portion and the pixel portion are formed over the substrate 200; however, the source driver circuit 201 that is the driver circuit portion and the pixel 202 are shown here.

The source driver circuit 201 is formed of a CMOS circuit in which an n-channel thin film transistor 221 and a p-channel thin transistor 222 are combined. Further, a thin film transistor for forming the driver circuit may be formed of a known CMOS circuit, PMOS circuit, or NMOS circuit. In this embodiment mode, an example in which the driver circuit is formed over the same substrate as the pixel portion; however, it is not always needed, and the driver circuit can be formed outside.

The pixel portion 202 is formed of a plurality of pixels each including a switching thin film transistor 211, a current control thin film transistor 212, and a first electrode 213 electrically connected to a drain of the current control thin film transistor 212. It is to be noted that an insulator 214 is formed to cover edge portions of the first electrode 213.

Further, in order to favorably form a layer 215 including a light emitting substance, which will be formed afterwards, the insulator 214 is preferably formed to have a curved surface having curvature in a cross section of a upper edge portion or a lower edge portion. For example, in a case where positive photosensitive acryl is used as a material of the insulator 214, it is preferable that only an upper edge portion of the insulator 214 has a curved surface with a curvature radius (0.2 μm to 3 μm). In addition, as the insulator 214, any of a negative type insulator that is to be insoluble into etchant by photosensitive light or a positive type insulator that is to be soluble into etchant by photosensitive light can be used. Furthermore, as a material of the insulator 214, an inorganic material such as silicon oxide or silicon oxynitride can be used as well as an organic material.

Over the first electrode 213, the layer 215 including a light emitting substance and a second electrode 216 are formed.

A light emitting element 217 including the first electrode 213, the layer 215 including a light emitting substance, and the second electrode 216 is a light emitting element having an anthracene derivative of the present invention. As long as an anthracene derivative of the present invention represented by any one of the general formulas (1) to (3) is used as a hole transporting material at least in one layer of the layer 215 including a light emitting substance, other materials are not particularly limited. It is to be noted that each material described in Embodiment Mode 3 can be selectively and appropriately used for the first electrode 213, the layer 215 including a light emitting substance, and the second electrode 216.

The sealing substrate 204 is attached to the substrate 200 with the use of the sealing material 205, whereby a structure, in which the light emitting element 217 is provided in the space 206 surrounded by the substrate 200, the sealing substrate 204, and the sealing material 205, is obtained. The space 206 includes a structure that is filled with the sealing material 205, in addition to a structure that is filled with an inert gas (such as nitrogen or argon).

As for the sealing material 205, an epoxy resign is preferably used. Further, these materials are preferable not to transmit moisture and oxygen as much as possible. As for a material used for the sealing substrate 204, in addition to a glass substrate and a quartz substrate, a plastic substrate made from FRP (Fiberglass-Reinforced Plastics), PVF (polyvinyl fluoride), myler, polyester, acryl, or the like can be used. As described above, a light emitting device can be manufactured.

In a case where both the first electrode 213 and the second electrode 216 are made of a substance having a light transmitting property, light emission can be extracted from both a first electrode 213 side and a second electrode 216 side. In a case where only the second electrode 216 is made of a substance having a light transmitting property, light emission can be extracted only from the second electrode 216 side. In this case, the first electrode 213 is preferably made of a material having high reflectivity. Alternatively, a film made of a material having high reflectivity (a reflective film) is preferably provided in a lower part of the first electrode 213. In a case where only the first electrode 213 is made of a substance having a light transmitting property, light emission can be extracted only from the first electrode 213 side. In this case, the second electrode 216 is preferably made of a material having high reflectivity. Alternatively, a reflective film is preferably provided in an upper part of the second electrode 216.

In the light emitting element 217, the layer 215 including a light emitting substance may be stacked so as to operate the light emitting element when applying a voltage so that potential of the second electrode 216 is higher than that of the first electrode 213. Alternatively, the layer 215 including a light emitting substance may be stacked so as to operate the light emitting element when applying a voltage so that potential of the second electrode 216 is lower than that of the first electrode 213.

As described above, by using an anthracene derivative of the present invention, which can be hardly crystallized, and can be superior in a carrier transporting property, as a hole transporting material, a highly reliable light transmitting device with a long lifetime and low power consumption can be obtained.

In this embodiment mode, an active-type light emitting device that controls driving of a light emitting element by a transistor is explained. However, a passive-type light emitting device, which drives a light emitting element without particularly providing a driving element such as a thin film transistor in each pixel, may be used.

It is to be noted that this embodiment mode can be freely combined with Embodiment Modes 1 to 3 and Embodiments 1 to 4 described below.

### Embodiment Mode 5

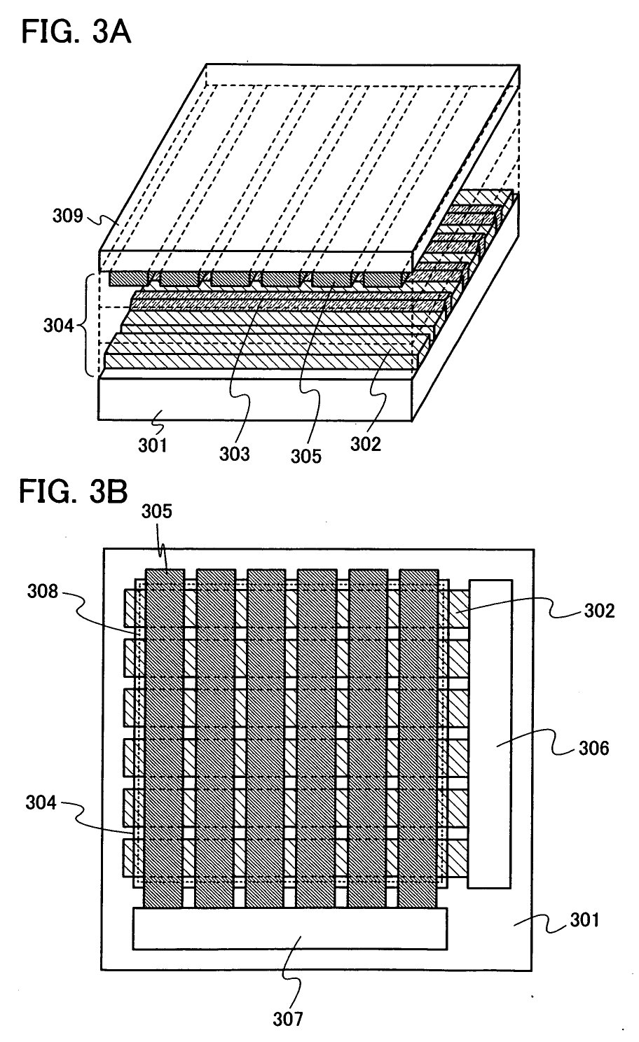

In this embodiment mode, one mode of a passive-type light emitting device to which the present invention is applied will be explained with reference to FIGS. 3A and 3B. FIGS. 3A and 3B are respectively a perspective view and a top view of a passive-type light emitting device to which the preset invention is applied. It is to be noted that FIG. 3A is a perspective view corresponding to a portion surrounded with a dot line 308 of FIG. 3B. In FIGS. 3A and 3B, corresponding portions to each other are denoted by using the same reference numerals. In FIG. 3A, a plurality of first electrodes 302 is provided in parallel over a first substrate 301. An edge portion of each of the first electrodes 302 is covered with a partition layer 303. An edge portion of the first electrode 302 that is positioned ahead is also covered with the partition layer 303; however, the partition layer 303 in that position is not shown in FIG. 3A in order to make an understandable structure in which the first electrodes 302 and the partition layers 303 are arranged. A plurality of second electrodes 305 is provided in parallel above the first electrodes 302 so as to intersect with the first electrodes 302. A layer 304 including a light emitting substance is provided between the first electrodes 302 and the second electrodes 305. In portions where the first electrodes 302 and the second electrodes 305 are intersected with each other, the layer 304 including a light emitting substance is interposed therebetween, whereby a light emitting element of the present invention is constituted. As long as an anthracene derivative of the present invention represented by any one of the general formulas (1) to (3) is used as a hole transporting material at least in one layer of the layer 304 including a light emitting substance, other materials are not particularly limited. Each material described in Embodiment Mode 3 can be selectively and appropriately used for the first electrodes 302, the layer 304 including a light emitting substance, and the second electrodes 305. Further, a second substrate 309 is provided over the second electrodes 305.

As shown in FIG. 3B, the first electrodes 302 are connected to a first driver circuit 306, and the second electrodes 305 are connected to a second driver circuit 307. Then, a light emitting element of the present invention, which is selected by a signal from the first driver circuit 306 and the second driver circuit 307, emits light. Light emission is extracted to outside through the first electrodes 302 and/or the second electrodes 305. Thereafter, an image is projected by combining light emission from a plurality of light emitting elements. In FIG. 3B, the partition layer 303 and the second substrate 309 are not shown in order to make understandable arrangement of each the first electrodes 302 and the second electrodes 305.

In a case where both the first electrodes 302 and the second electrodes 305 are made of a substance having a light transmitting property, light emission can be extracted from both the first electrodes 302 side and the second electrodes 305 side. In a case where only the second electrodes 305 are made of a substance having a light transmitting property, light emission can be extracted only from the second electrodes 305 side. In this case, the first electrodes 302 are preferably made of a substance having high reflectivity. Alternatively, a film made of a material having high reflectivity (a reflective film) is preferably provided in a lower part of the first electrodes 302. In a case where only the first electrodes 302 are made of a substance having a light transmitting property, light emission can be extracted only from the first electrode 302 side. In this case, the second electrodes 305 are preferably made of a material having high reflectivity. Alternatively, a reflective film is preferably provided in an upper part of the second electrodes 305. The partition layer 303 can be formed using the same material as that of the insulator 214 described in Embodiment Mode 4.

As described above, by using an anthracene derivative of the present invention as a hole transporting material, which can be hardly crystallized, and can be superior in a carrier transporting property, a highly reliable light emitting device with a long lifetime and low power consumption can be obtained.

It is to be noted that this embodiment mode can be freely combined with Embodiment Modes 1 to 3 and Embodiments 1 to 4 described below.

### Embodiment Mode 6

In this embodiment mode, various electronic appliances will be explained, each of which is completed by using a light emitting device having a light emitting element of the present invention. An anthracene derivative included in the light emitting element of the present invention can be hardly crystallized, and can be superior in a carrier transporting property. Therefore, a highly reliable light emitting device with long lifetime and low power consumption can be obtained.

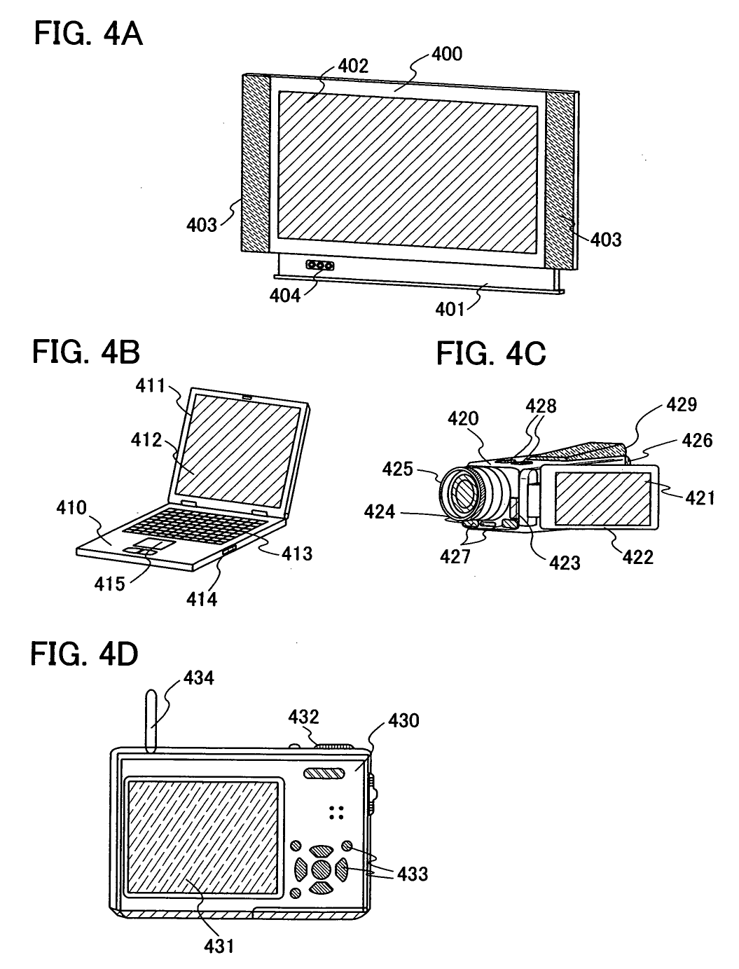

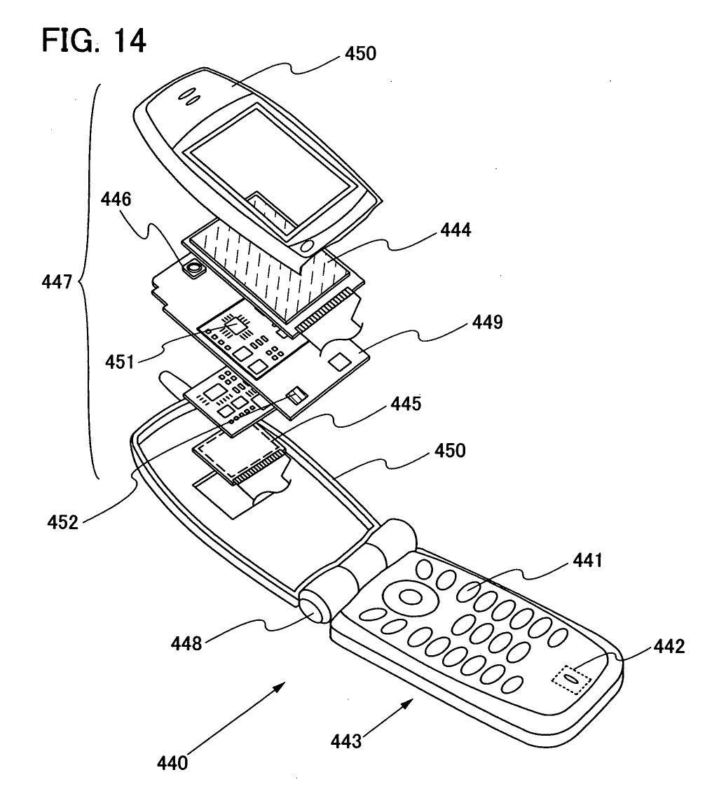

As an electronic appliance manufactured by using a light emitting device of the present invention, the following can be given: a television, a camera such as a video camera or a digital camera, a goggle type display (head mounted display), a navigation system, an audio reproducing device (a car audio, an audio component, or the like), a personal computer, a game machine, a portable information terminal (a mobile computer, a cellular phone, a portable game machine, an electronic book, or the like), an image reproducing device including a recording medium (specifically, a device reproducing a recording medium such as a digital versatile disc (DVD) and including a display device which can display the image), and the like. Specific examples of some electronic appliances will be explained with the use of FIGS. 4A to 4D and FIG. 14. An electronic appliance using a light emitting device of the present invention is not limited to these illustrated specific examples.

FIG. 4A shows a display device, which includes a chassis 400, a supporting base 401, a display portion 402, speaker portions 403, a video input terminal 404, and the like. The display device is manufactured by using a light emitting device that is formed by implementing the present invention for the display portion 402. It is to be noted that the display device includes all devices for information display, such as for computers, for receiving TV broadcastings, for displaying advertisements, and the like.

A light emitting element of the present invention is provided in the display portion 402. The light emitting element includes a layer using an anthracene derivative represented by any one of the general formulas (1) to (3) as a hole transporting material. Therefore, by using the light emitting element of the present invention, a highly reliable display device with a long lifetime and low power consumption can be obtained.

FIG. 4B shows a personal computer, which includes a main body 410, a chassis 411, a display portion 412, a key board 413, an external connecting port 414, a pointing mouse 415, and the like.

A light emitting element of the present invention is provided in the display portion 412. The light emitting element includes a layer using an anthracene derivative represented by any one of the general formulas (1) to (3) as a hole transporting material. Therefore, by using the light emitting element of the present invention, a personal computer including a highly reliable display portion with a long lifetime and low power consumption can be obtained.

FIG. 4C shows a video camera, which includes a main body 420, a display portion 421, a chassis 422, an external connecting port 423, a remote control receiving portion 424, an image receiving portion 425, a battery 426, an audio input portion 427, operation keys 428, an eye piece portion 429, and the like.

A light emitting element of the present invention is provided in the display portion 421. The light emitting element includes a layer using an anthracene derivative represented by any one of the general formulas (1) to (3) as a hole transporting material. Therefore, by using the light emitting element of the present invention, a video camera including a highly reliable display portion with a long lifetime and low power consumption can be obtained.

FIG. 4D shows a digital camera, which includes a main body 430, a display portion 431, a shutter 432, operation keys 433, an antenna 434, an imaging portion, and the like. It is to be noted that FIG. 4D is a view on a display portion 431 side, and the imaging portion is not shown.

A digital camera of the present invention may make the display portion 431 function as a display medium such as a television receiver by receiving signals such as an image signal and an audio signal from the antenna 434. It is to be noted that a speaker, an operation switch, or the like may be appropriately provided when the display portion 431 serves as a display medium.

A light emitting element of the present invention is provided in the display portion 431. The light emitting element includes a layer using an anthracene derivative represented by any one of the general formulas (1) to (3) as a hole transporting material. Therefore, by using the light emitting element of the present invention, a digital camera including a highly reliable display portion with a long lifetime and low power consumption can be obtained.

FIG. 14 shows a cellular phone 440, which includes a main body (A) 443 provided with operation switches 441, a microphone 442, and the like; and a main body (B) 447 provided with a display panel (A) 444, a display panel (B) 445, a speaker 446, and the like. The main body (A) 443 and the main body (B) 447 are connected to each other with a hinge 448 so as to be opened and closed. The display panel (A) 444 and the display panel (B) 445 are incorporated together with a circuit board 449 into a chassis 450 of the main body (B) 447. Pixel portions of the display panel (A) 444 and the display panel (B) 445 are arranged to be seen from an opening window formed in the chassis 450. The circuit board 449 is provided with a signal processing circuit 451 and an optical sensor 452. This photo-optical sensor 452 is provided for measuring external light intensity.

In the display panel (A) 444 and the display panel (B) 445, a pixel is formed by using a light emitting element that is manufactured using an anthracene derivative of the present invention as described in Embodiment Mode 3. As for the number of the pixels in the display panel (A) 444 and the display panel (B) 445, a specification can be appropriately set in accordance with a function of the cellular phone 440. For example, the display panel (A) 444 as a main display screen and the display panel (B) 445 as a sub-display screen can be combined. In this case, the display panel (A) 444 can be made to be an active display panel as shown in FIGS. 2A and 2B, and the display panel (B) 445 can be made to be a passive display panel as shown in FIGS. 3A and 3B to be combined.

Then, the display panel (A) 444 can be set as a color display screen having high-definition for displaying characters and images, and the display panel (B) 445 can be set as a unicolor information display screen for displaying character information. In particular, the display panel (A) 444 has highly definition as an active matrix type, thereby displaying various character information and improving information display density for each pixel. For example, the display panel (A) 444 can be set to be 2 to 2.5 inches with 64 grayscales and 260,000 colors as a QVGA (320 dots×240 dots), and the display panel (B) 445 can be set to be 180 to 220 PPI with unicolor and 2 to 8 grayscale, so as to display alphabets, hiragana, katakana, Chinese characters, Hangul characters, pictorial symbols, determinate characters, and the like.

An anthracene derivative of the present invention, which can be hardly crystallized, and can be superior in a carrier transporting property, is used as a hole transporting material in one or both of the display panel (A) 444 and the display panel (B) 445, whereby a highly reliable cellular phone with a long lifetime and low power consumption can be obtained. Thus, long continuous use is enabled, and the battery can be made small. Therefore, the cellular phone can be achieved to be downsized.

As described above, an application range of the present invention is extremely wide, and the present invention can be used in a display device of various fields. Further, the electronic appliance relating to this embodiment mode can be appropriately combined with any structure of Embodiment Modes 1 to 5 and Embodiments 1 to 4 described below.

### Embodiment 1

A synthesis example of an organometallic complex of the present invention will be explained. However, the present invention is not limited to an organometallic complex of a synthesis example described below.

### SYNTHESIS EXAMPLE 1

This synthesis example shows a synthesis example of 9,10-di(4-phenylphenyl)-2-tert-butylanthracene (abbreviation: t-BuDBA) represented by the structural formula (4).

(Step 1)

100 mL of dried tetrahydrofran (abbreviation: THF) solution containing 10.15 g of p-bromobiphenyl was cooled to −78° C., and 27.6 mL of n-butyllithium hexane (1.58 mol/L) solution was dropped therein. After the drop, the solution was stirred at −78° C. for 30 minutes. Then, about 50 mL of a THF solution containing 5 g of 2-tert-butylanthraquinone was dropped at −78° C. and after the dropping, the solution was stirred at a room temperature for 5 hours. Water was added to this solution and a product was extracted by using ethyl acetate. After an obtained organic layer was dried with magnesium sulfate, a solvent was concentrated. Finally, a residue was purified with silica gel chromatography (an developing solution: hexane-ethyl acetate) to obtain 9,10-di(4-phenylphenyl)-2-tert-butyl-9,10-dihydroxy-9,10-dihydroanthracene (a compound B). A synthesis scheme (b-1) of Step 1 is shown below.

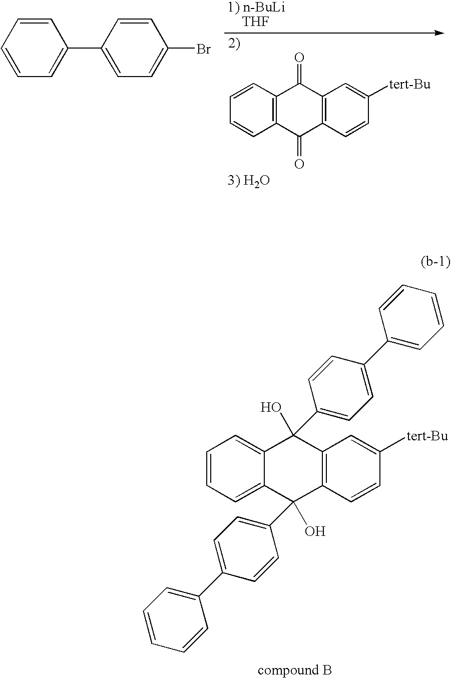

(Step 2)

The 9,10-di(4-phenylphenyl)-2-tert-butyl-9,10-dihydroxy-9,10-dihydroanthracene (the compound B) that is obtained by the above step was dissolved in 170 mL of acetic acid, and 10.9 g of potassium iodide and 22.16 g of sodium phosphate acid monohydrate were added to perform reflux for 2 hours. After a reaction solution was cooled, a product was extracted by using toluene. After a toluene layer was washed with water and a salt solution and dried with magnesium sulfate, a solvent was concentrated. A obtained residue was recrystallized by using toluene and hexane to obtain 8.33 g of 9,10-di(4-phenylphenyl)-2-tert-butylanthracene (light yellow solid, total yield: 56%). A synthesis scheme (b-2) of Step 2 is shown below.

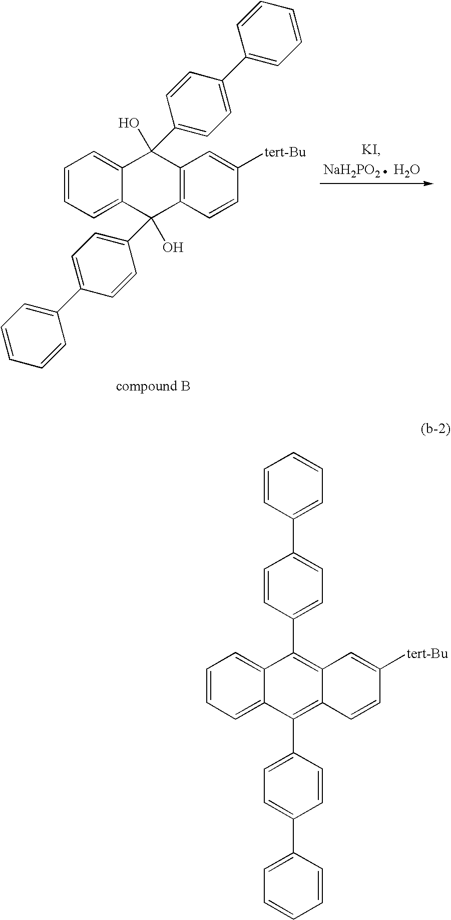

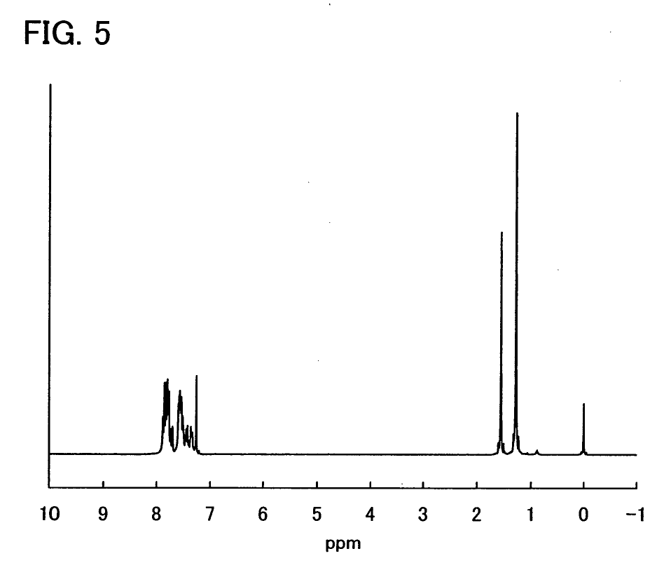

When the obtained solid was analyzed by a nuclear magnetic resonance spectrometry (¹H-NMR), the following result could be obtained, and it was found that the obtained solid was 9,10-di(4-phenylphenyl)-2-tert-butylanthracene (abbreviation: t-BuDBA) that is one of anthracene derivatives of the present invention. FIG. 5 shows an ¹H-NMR chart of t-BuDBA.

¹H-NMR δ(CDCl₃): 7.89-7.70 (m, 12H), 7.59-7.31 (m, 13H), 1.28 (s, 9H)

While argon flowed with flow rate of 3.0 mL/min, the obtained 3.46 g of t-BuDBA was purified through sublimation with pressure of 6.7 Pa at a temperature of 270° C. for 12 hours. As a result, 2.70 g of t-BuDBA was obtained, and a yield rate was 78%.

Since the obtained t-BuDBA has a high volume structure, crystallization and dimerization of an anthracene skeleton can be suppressed. Further, the t-BuDBA is superior in a carrier transporting property.

### Embodiment 2

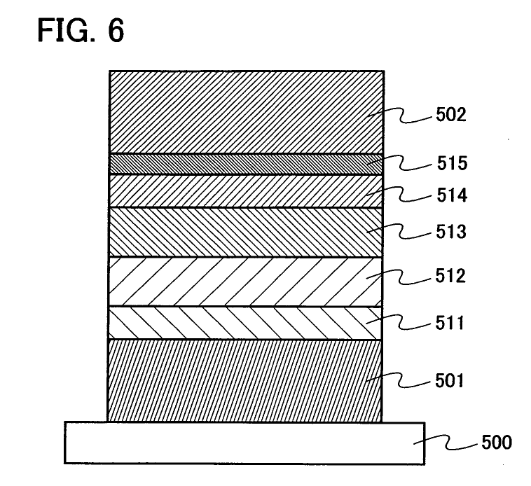

In this embodiment, a method for manufacturing a light emitting element in which 9,10-di(4-phenylphenyl)-2-tert-butylanthracene (abbreviation: t-BuDBA) synthesized by Synthesis Example 1 is used as a hole transporting layer, and operation characteristics of the light emitting element will be explained with reference to FIG. 6.

First, indium tin oxide containing silicon oxide was deposited by a sputtering method over a glass substrate 500 to form a first electrode 501. It is to be noted that a thickness of the first electrode 501 was 110 nm, and an electrode area was 2 mm×2 mm.

Next, the glass substrate 500 provided with the first electrode 501 was fixed to a substrate holder provided in a vacuum evaporation system so that a surface over which the first electrode 501 was formed was placed downward. Then, contents in the vacuum evaporation system were exhausted and pressure was reduced to approximately 10 Pa. Thereafter, t-BuDNA and molybdenum trioxide were deposited to have a thickness of 50 nm over the first electrode 501 by co-evaporation to form a hole injecting layer 511. A ratio of molybdenum oxide in the hole injecting layer was adjusted so that molybdenum oxide was contained at 10 vol % in a volume ratio.

Subsequently, t-BuDBA was deposited to have a thickness of 10 nm by an evaporation method using resistance heating to form a hole transporting layer 512.

In addition, Alq and DPQd were co-evaporated to form a light emitting layer 513 having a thickness of 40 nm over the hole transporting layer 512. Here, a mass ratio of Alq and DPQd was adjusted to be 1:0.005 (=Alq:DPQd). Thus, DPQd was dispersed in a layer made of Alq.

Thereafter, Alq was deposited to have a thickness of 30 nm over the light emitting layer 513 by an evaporation method using resistance heating to form an electron transporting layer 514.

Further, lithium fluoride was deposited to have a thickness of 1 nm over the electron transporting layer 514 by an evaporation method using resistance heating to form an electron injecting layer 515.

Finally, aluminum was deposited to have a thickness of 200 nm over the electron injecting layer 515 by an evaporation method using resistance heating to form a second electrode 502.

As described above, the hole injecting layer 511, the hole transporting layer 512, the light emitting layer 513, the electron transporting layer 514, and the electron injecting layer 515 were stacked between the first electrode 501 and the second electrode 502 to manufacture a light emitting element.

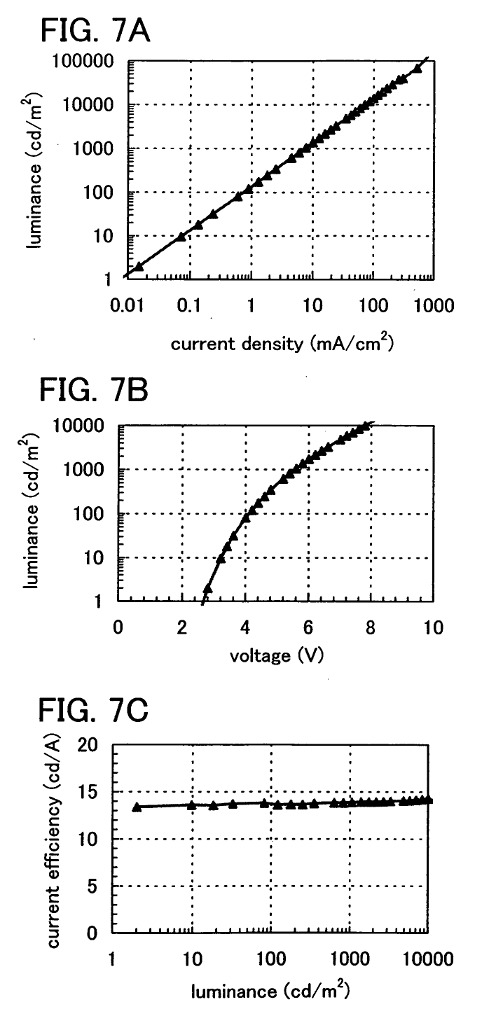

Further, the obtained light emitting element was sealed under a nitrogen atmosphere by using a sealing material without exposing the obtained light emitting element to an atmosphere. A voltage was applied to the light emitting element shown in this embodiment so that potential of the first electrode 501 was higher than that of the second electrode 502, and then, operation characteristics of the light emitting element were examined. It is to be noted that measurement was performed under condition keeping a room temperature (25° C.). A result is shown in FIGS. 7A to 7C. FIG. 7A shows a measurement result of current density-luminance characteristics. FIG. 7B shows a measurement result of voltage-luminance characteristics. FIG. 7C shows a measurement result of luminance-current efficiency characteristics. In FIG. 7A, a horizontal axis indicates current density (mA/cm²), and a vertical axis indicates luminance (cd/m²). In FIG. 7B, a horizontal axis indicates a voltage (V), and a vertical axis indicates luminance (cd/m²). In FIG. 7C, a horizontal axis indicates luminance (cd/m²), and a vertical axis indicates current efficiency (cd/A).

According to these results, it was found that the light emitting element of this embodiment emitted light with luminance of 1063 cd/m² when applying a voltage of 5.6 V, and a current flowing at that time was 0.31 mA (current density was 7.65 mA/cm²). Current efficiency at this time was 13.9 cd/A.

As described above, by using an anthracene derivative of the present invention, which can be hardly crystallized, and can be superior in a carrier transporting property, as a hole transporting layer, a light emitting element in which a driving voltage is low could be obtained. Furthermore, a lifetime of a light emitting element can be lengthened.

### Embodiment 3

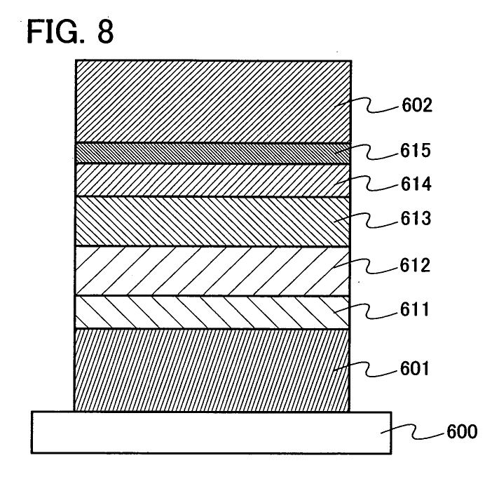

In this embodiment, a method for manufacturing a light emitting element in which a layer having 9,10-di(4-phenylphenyl)-2-tert-butylanthracene (abbreviation: t-BuDBA) synthesized by the method described in Synthesis Example 1 is used as a layer in contact with an anode, and operation characteristics of the light emitting element will be explained with reference to FIG. 8.

First, indium tin oxide containing silicon oxide was deposited over a glass substrate 600 by a sputtering method to form a first electrode 601. It is to be noted that a thickness of the first electrode 601 was 110 nm, and an electrode area was 2 mm×2 mm.

Next, the substrate provided with the first electrode was fixed to a substrate holder provided in a vacuum evaporation system so that a surface over which the first electrode 601 was formed was placed downward. Then, contents in the vacuum evaporation system were exhausted and pressure was reduced to approximately 104 Pa. Thereafter, t-BuDBA and molybdenum trioxide were deposited to have a thickness of 50 nm over the first electrode 601 by co-evaporation to form a layer 611. A ratio of molybdenum oxide in the layer 611 was adjusted so that the molybdenum oxide was contained at 10 vol % in a volume ratio.

Subsequently, NPB was deposited to have a thickness of 10 nm by an evaporation method using resistance heating to form a hole transporting layer 612.

In addition, Alq and DPQd were co-evaporated to form a light emitting layer 613 having a thickness of 40 nm over the hole transporting layer 612. Here, a mass ratio of Alq and DPQd was adjusted to be 1:0.005 (=Alq:DPQd). Thus, DPQd is dispersed in a layer made of Alq.

Thereafter, Alq was deposited to have a film thickness of 30 nm over the light emitting layer 613 by an evaporation method using resistance heating to form an electron transporting layer 614.

Furthermore, lithium fluoride was deposited to have a thickness of 1 nm over the electron transporting layer 614 by an evaporation method using resistance heating to form an electron injecting layer 615.

Finally, aluminum was deposited to have a thickness of 200 nm over the electron injecting layer 615 by an evaporation method using resistance heating to form a second electrode 602.

As described above, the layer 611, the hole transporting layer 612, the light emitting layer 613, the electron transporting layer 614, and the electron injecting layer 615 were stacked between the first electrode 601 and the second electrode 602 to manufacture a light emitting element.

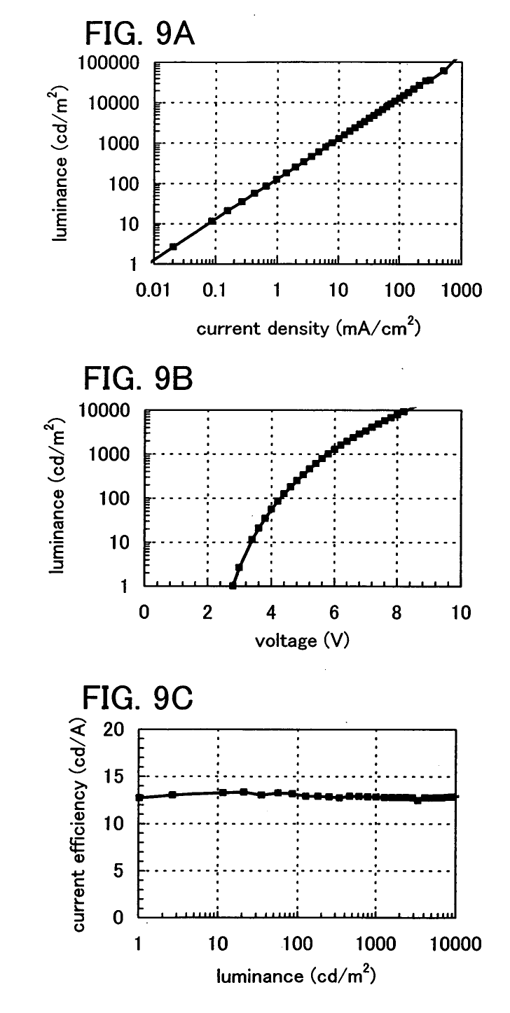

Further, the obtained light emitting element was sealed under a nitrogen atmosphere by using a sealing material without exposing the obtained light emitting element to an atmosphere. A voltage was applied to the light emitting element shown in this embodiment so that potential of the first electrode 601 was higher than that of the second electrode 602, and then, operation characteristics of the light emitting element were examined. It is to be noted that measurement was performed under condition keeping a room temperature (25° C.). A result thereof is shown in FIGS. 9A to 9C. FIG. 9A shows a measurement result of current density-luminance characteristics. FIG. 9B shows a measurement result of voltage-luminance characteristics. Further, FIG. 9C shows luminance-current efficiency characteristics.

According to these results, it was found that the light emitting element of this embodiment emitted light with luminance of 1010 cd/m² when applying a voltage of 5.8 V, and a flowing current at that time was 0.31 mA (current density was 7.87 mA/cm²). Further, current efficiency at this time was 12.8 cd/A.

Above described above, by using an anthracene derivative of the present invention, which can be hardly crystallized, and can be superior in a carrier transporting property, in a light emitting element, a light emitting element in which a driving voltage is low could be obtained.

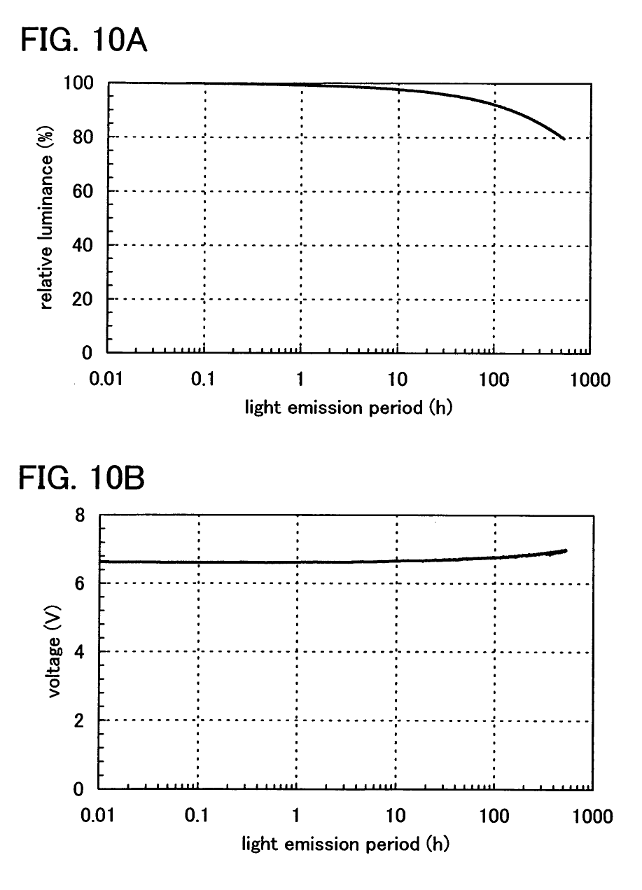

Further, a reliability test of the manufactured light emitting element was performed as follows. In an initial state, a current continuously flowed, of which a value is the same as that of the current flowing into the light emitting element that emits light with luminance of 3000 cd/m². Then, every time a certain time period passed, luminance was measured. Results obtained by the reliability test are shown in FIGS. 10A and 10B. FIG. 10A shows variation of luminance with time. FIG. 10B shows variation of a voltage with time. In FIG. 10A, a horizontal axis indicates a light emission period (h), and a vertical axis indicates a ratio of luminance in each time period with respect to an initial luminance, that is, relative luminance (%). In FIG. 10B, a horizontal axis indicates a light emission period (h), and a vertical axis indicates a voltage (V).

According to FIG. 10A, it was found that reduction of luminance due to variation with time was small in the manufactured light emitting element, and even after 520 h, luminance that is 80% of the initial luminance could be held. According to FIG. 10B, it was found that a voltage was hardly increased with time.

As described above, it was found that a light emitting element using an anthracene derivative of the present invention has a low driving voltage, a long lifetime, and high reliability.

### Embodiment 4

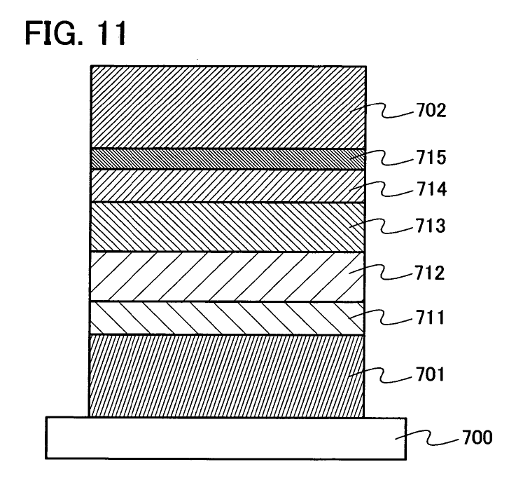

In this embodiment, a method for manufacturing a light emitting element in which a layer having 9,10-di(4-phenylphenyl)-2-tert-butylanthracene (abbreviation: t-BuDBA) synthesized by the method described in Synthesis Example 1 is used as a layer in contact with an anode and a hole transporting layer, and operation characteristics of the light emitting element will be explained with reference to FIG. 11.

First, indium tin oxide containing silicon oxide was deposited over a glass substrate 700 by a sputtering method to form a first electrode 701. It is to be noted that a thickness of the first electrode 701 was 110 nm, and an electrode area was 2 nm×2 nm.

Next, the glass substrate 700 provided with the first electrode 701 was fixed to a substrate holder provided in a vacuum evaporation system so that a surface over which the first electrode 701 was formed was placed downward. Then, contents in the vacuum evaporation system were exhausted, and pressure was reduced to approximately 10⁻⁴ Pa. Thereafter, t-BuDBA and molybdenum trioxide were deposited to have a film thickness of 50 nm over the first electrode 701 by co-evaporation to form a layer 711. A ratio of molybdenum oxide in the layer 711 was adjusted so that the molybdenum oxide was contained at 10 vol % in a volume ratio.

Next, t-BuDBA was deposited to have a thickness of 10 nm by an evaporation method using resistance heating to form a hole transporting layer 712.

In addition, Alq and DPQd were co-evaporated to form a light emitting layer 713 having a thickness of 40 nm over the hole transporting layer 712. Here, a mass ratio of Alq and DPQd was adjusted to be 1:0.005 (=Alq:DPQd). Thus, DPQd is dispersed in a layer made of Alq.

Thereafter, Alq was deposited to have a thickness of 30 nm over the light emitting layer 713 by an evaporation method using resistance heating to form an electron transporting layer 714.

Furthermore, lithium fluoride was deposited to have a thickness of 1 nm over the electron transporting layer 714 by an evaporation method using resistance heating to form an electron injecting layer 715.

Finally, aluminum was deposited to have a thickness of 200 nm over the electron injecting layer 715 by an evaporation method using resistance heating to form a second electrode 702.

As described above, the layer 711, the hole transporting layer 712, the light emitting layer 713, the electron transporting layer 714, and the electron injecting layer 715 were stacked between the first electrode 701 and the second electrode 702 to manufacture a light emitting element.

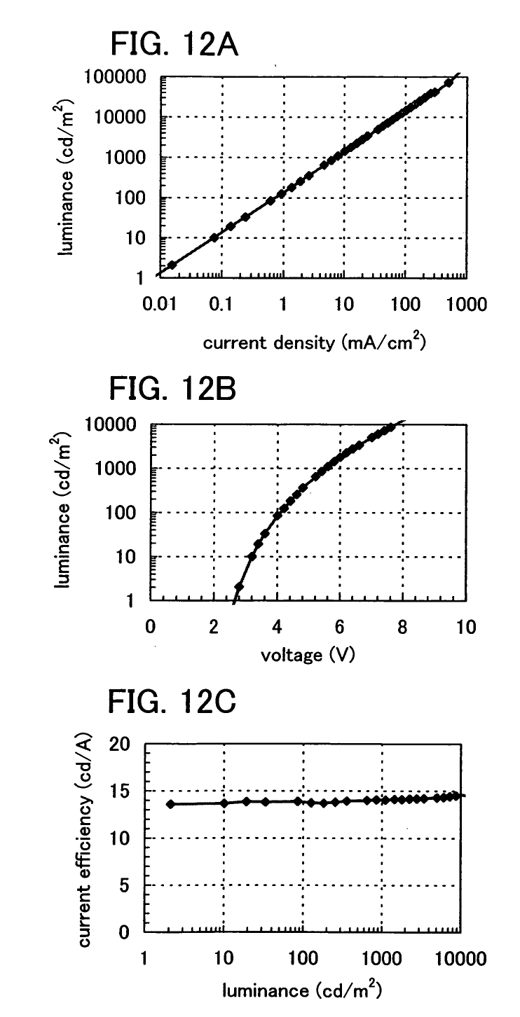

Further, the obtained light emitting element was sealed under a nitrogen atmosphere by using a sealing material without exposing the obtained light emitting element to an atmosphere. A voltage was applied to the light emitting element shown in this embodiment so that potential of the first electrode 701 was higher than that of the second electrode 702, and then, operation characteristics of the light emitting element were examined. The measurement was performed under condition keeping a room temperature (25° C.). A result thereof is shown in FIGS. 12A to 12C. FIG. 12A shows a measurement result of current density-luminance characteristics. FIG. 12B shows a measurement result of voltage-luminance characteristics. Further, FIG. 12C shows a measurement result of luminance-current efficiency characteristics.

According to theses results, it was found that the light emitting element of this embodiment emitted light with luminance of 1105 cd/m² when applying a voltage of 5.6 V, and a flowing current at that time was 0.31 mA (current density was 7.86 mA/cm²). Further, current efficiency at this time was 14.1 cd/A.

As described above, by using an anthracene derivative of the present invention, which can be hardly crystallized, and can be superior in a carrier transporting property, in a light emitting element, a light emitting element in which a driving voltage is low could be obtained.

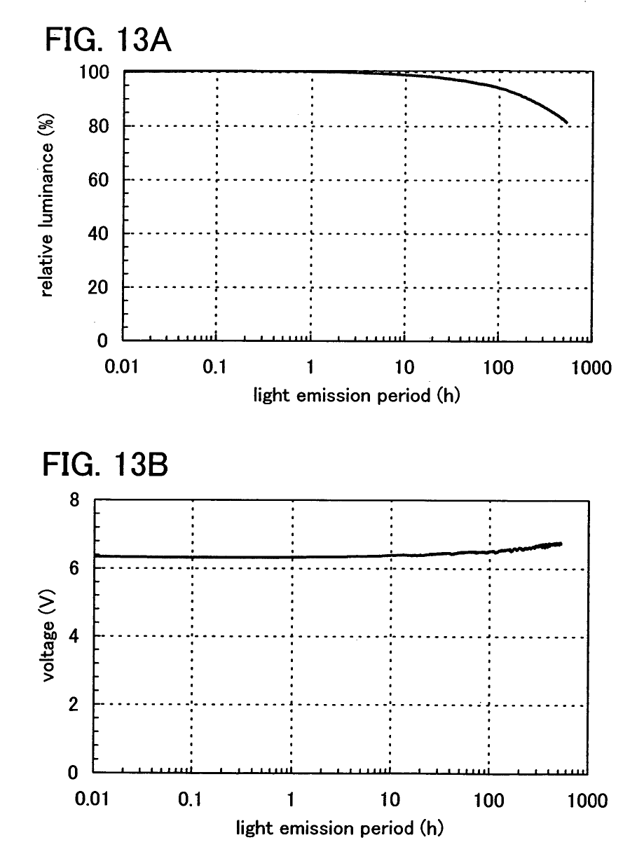

Further, a reliability test of the manufactured light emitting element was performed similarly to Embodiment 3. In an initial state, a current continuously flowed, of which a value is the same as the current flowing into the light emitting element that emits light with luminance of 3000 cd/m². Then, every time a certain period time passed, luminance was measured. Results obtained by the reliability test are shown in FIGS. 13A and 13B. FIG. 13A shows variation of luminance with time, and FIG. 13B shows variation of a voltage with time.

According to FIG. 13A, it was found that reduction of luminance due to variation with time was small in the manufactured light emitting element, and even after 520 h, luminance that is 81% of the initiate luminance could be kept. Further, according to FIG. 13B, it was found that a voltage was hardly increased with time.

As described above, it was fount that a light emitting element using an anthracene derivative of the present invention has a low driving voltage, a long lifetime, and high reliability.

### Embodiment 5

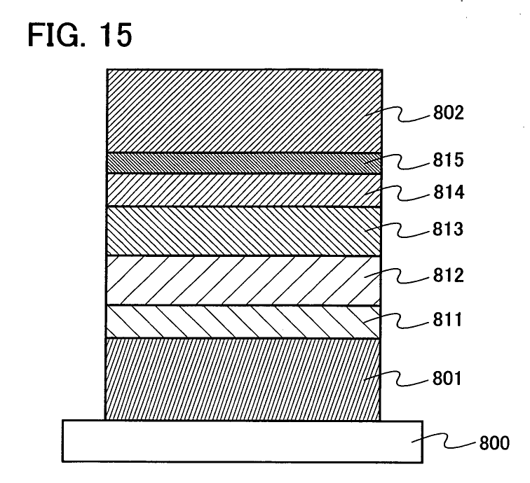

In this embodiment, a method for manufacturing a light emitting element in which a layer having 9,10-di(4-phenylphenyl)-2-tert-butylanthracene (abbreviation: t-BuDBA) synthesized by the method described in Synthesis Example 1 is used as a light emitting layer, and operation characteristics of the light emitting element will be explained with reference to FIG. 15.

First, indium tin oxide containing silicon oxide was deposited over a glass substrate 800 by a sputtering method to form a first electrode 801. It is to be noted that a thickness of the first electrode 801 was 110 nm, and an electrode area was 2 mm×2 mm.

Next, the glass substrate 800 provided with the first electrode 801 was fixed to a substrate holder provided in a vacuum evaporation system so that a surface over which the first electrode 801 was formed was placed downward. Then, contents in the vacuum evaporation system were exhausted, and pressure was reduced to approximately 10⁻⁴ Pa. Thereafter, DNTPD and molybdenum trioxide were deposited to have a thickness of 50 nm over the first electrode 801 by co-evaporation to form a layer 811. A mass ratio of DNTPD and molybdenum oxide were adjusted to be 4:2 (=DNTPD:molybdenum oxide).

Subsequently, NPB was deposited to have a thickness of 10 nm by an evaporation method using resistance heating to form a hole transporting layer 812.

In addition, t-BuDBA and YGAPA were co-evaporated to form a light emitting layer 813 having a thickness of 30 nm over the hole transporting layer 812. Here, a mass ratio of t-BuDBA and YGAPA was adjusted to be 1:0.04 (=t-BuDBA:YGAPA). Thus, YGAPA was dispersed in a layer made of t-BuDBA.

Then, Alq was deposited to have a thickness of 10 nm over the light emitting layer 813 by an evaporation method using resistance heating to form an electron transporting layer 814.

In addition, an electron injecting layer 815 including Alq₃ and Li was formed to have a thickness of 20 nm over the electron transporting layer 814 by co-evaporation. A mass ratio of Alq₃ and Li was adjusted to be 1:0.01 (=Alq₃:Li).

Finally, aluminum was deposited to have a thickness of 200 nm over the electron injecting layer 815 by an evaporation method using resistance heating to form a second electrode 802.

As described above, the layer 811, the hole transporting layer 812, the light emitting layer 813, the electron transporting layer 814, and the electron injecting layer 815 were stacked between the first electrode 801 and the second electrode 802 to manufacture a light emitting element.

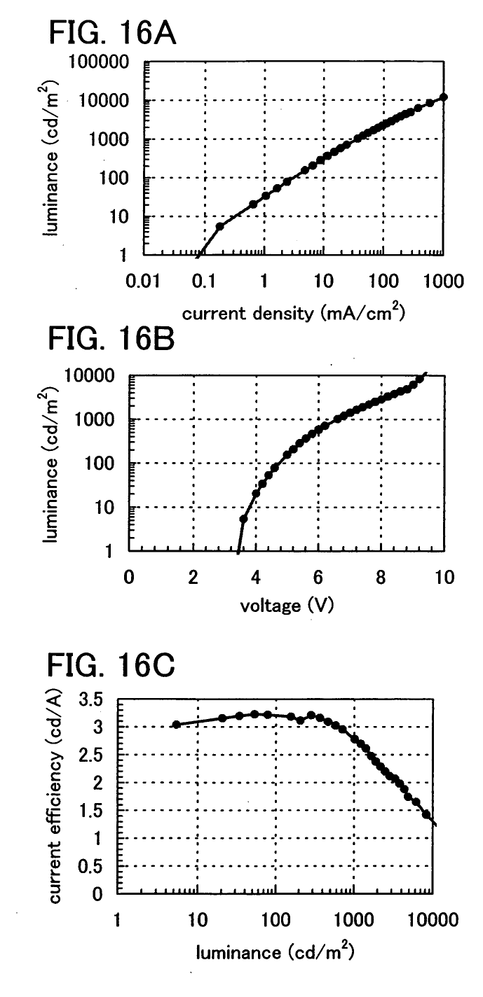

Further, the obtained light emitting element was sealed under a nitrogen atmosphere by using a sealing material without exposing the obtained light emitting element to an atmosphere. A voltage was applied to the light emitting element shown in this embodiment so that potential of the first electrode 801 was higher than that of the second electrode 802, and then, operation characteristics of the light emitting element were examined. It is to be noted that measurement was performed under condition keeping a room temperature (25° C.). A result thereof is shown in FIGS. 16A to 16C. FIG. 16A shows a measurement result of current density-luminance characteristics. FIG. 16B shows a measurement result of voltage-luminance characteristics. Further, FIG. 16C shows a measurement result of luminance-current efficiency characteristics.

According to theses results, it was found that the light emitting element in this embodiment emitted light with luminance of 1017 cd/m² when applying a voltage of 6.6 V, and a flowing current at that time was 1.46 mA (current density was 36.6 mA/cm²). Further, current efficiency at this time was 2.78 cd/A.

As described above, by using an anthracene derivative of the present invention, which can be hardly crystallized, and can be superior in a carrier transporting property, in a light emitting element, a light emitting element in which a driving voltage is low could be obtained.

This application is based on Japanese Patent Application serial No. 2005-247021 filed in Japan Patent Office on Aug. 29, 2005 and Japanese Patent Application serial No. 2005-249899 filed in Japan Patent Office on Aug. 30, 2005, the entire contents of which are hereby incorporated by reference.

1. An anthracene derivative represented by a general formula (1), 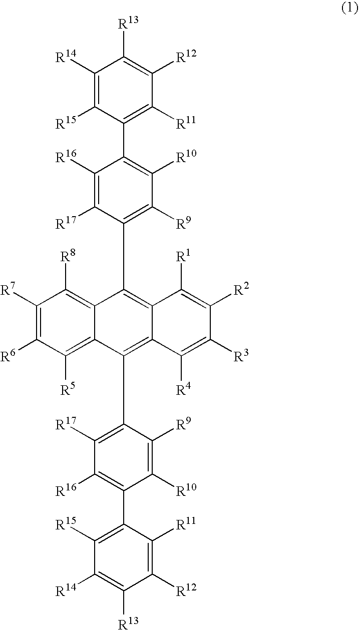
wherein each of R¹ to R⁸ represents hydrogen or an alkyl group having 1 to 4 carbon atoms, and each of R⁹ to R¹⁷ represents hydrogen, an alkyl group having 1 to 4 carbon atoms, or a substituted or unsubstituted aryl group.

2. An anthracene derivative represented by a general formula (2), 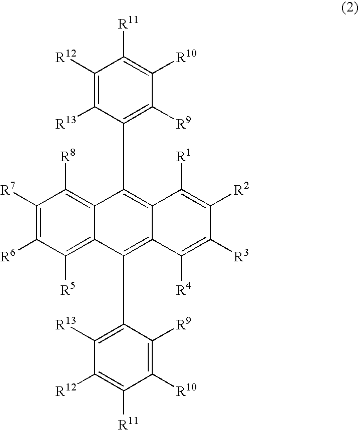
wherein each of R¹ to R⁸ represents hydrogen or an alkyl group having 1 to 4 carbon atoms, and each of R⁹ to R¹³ represents hydrogen, an alkyl group having 1 to 4 carbon atoms, or a substituted or unsubstituted aryl group.

3. An anthracene derivative represented by a general formula (3), 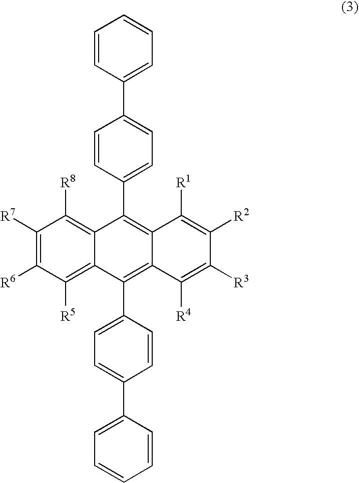
wherein each of R¹ to R⁸ represents hydrogen or an alkyl group having 1 to 4 carbon atoms.

4. An anthracene derivative according to any one of claims 1 to 3, wherein any one of the R¹ to R⁸ is an alkyl group having 3 carbon atoms.

5. An anthracene derivative represented by a structural formula (4).

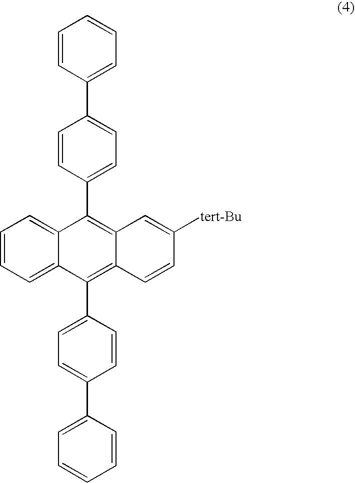

6. A hole transporting material that is an anthracene derivative represented by a general formula (1), 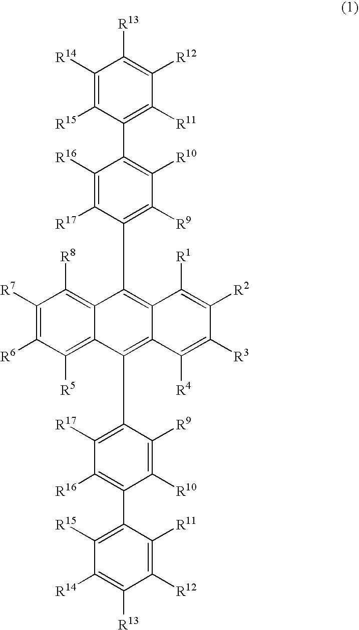
wherein each of R¹ to R⁸ represents hydrogen or an alkyl group having 1 to 4 carbon atoms, and each of R⁹ to R¹⁷ represents hydrogen, an alkyl group having 1 to 4 carbon atoms, or a substituted or unsubstituted aryl group.

7. A hole transporting material that is an anthracene derivative represented by a general formula (2), 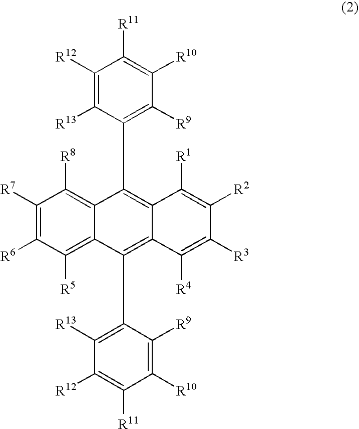
wherein each of R¹ to R⁸ represents hydrogen or an alkyl group having 1 to 4 carbon atoms, and each of R⁹ to R¹³ represents hydrogen, an alkyl group having 1 to 4 carbon atoms, or a substituted or unsubstituted aryl group.

8. A hole transporting material that is an anthracene derivative represented by a general formula (3), 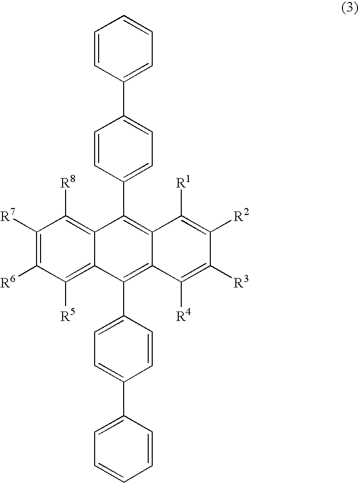
wherein each of R¹ to R⁸ represents hydrogen or an alkyl group having 1 to 4 carbon atoms.

9. A hole transporting material according to any one of claims 6 to 8, wherein any one of the R¹ to R⁸ is an alkyl group having 3 carbon atoms.

10. A hole transporting material that is an anthracene derivative represented by a structural formula (4).

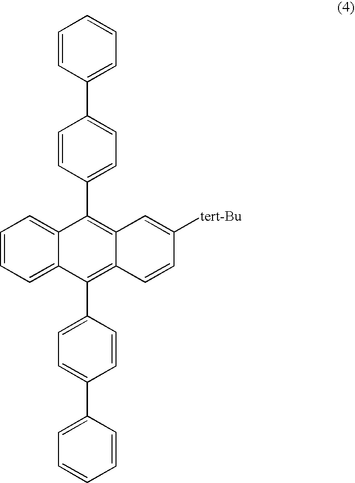

11. A light emitting element having an anthracene derivative according to any one of claims 1, 2, 3, and 5 between a pair of electrodes.

12. A light emitting element having a hole transporting material according to any one of claims 6 to 8 between a pair of electrodes.

13. A light emitting element having a hole transporting material according to claim 10 between a pair of electrodes.

14. A light emitting element having a hole transporting layer including a hole transporting material according to any one of claims 6 to 8,
wherein the hole transporting layer has a multi-layer structure in which two or more layers are formed of anthracene derivatives, each of which represented by any one of the general formulas (1) to (3).

15. A light emitting device using a light emitting element described in claim 11 in a pixel portion.

16. An electronic appliance including a light emitting element described in claim 11 at least in a display portion or a light source portion, and a control portion for driving the light emitting element.
